(19) United States
(12) Patent Application Publication
(10) Pub. No.: US 2025/0393298 A1
(43) Pub. Date: Dec. 25, 2025

(54) SEMICONDUCTOR STRUCTURE WITH SOURCE/DRAIN ISOLATION FEATURES

(71) Applicant: TAIWAN SEMICONDUCTOR MANUFACTURING COMPANY, LTD., Hsinchu (TW)

(72) Inventors: Ta-Chun LIN, Hsinchu (TW); Jhon Jhy LIAW, Hsinchu (TW)

(73) Assignee: TAIWAN SEMICONDUCTOR MANUFACTURING COMPANY, LTD., Hsinchu (TW)

(21) Appl. No.: 18/750,820

(22) Filed: Jun. 21, 2024

(51) Int. Cl. H01L 27/088; H01L 29/06; H01L 29/417; H01L 29/423; H01L 29/66; H01L 29/775; H01L 29/786

(52) U.S. Cl. CPC H10D 84/83; H10D 30/014; H10D 30/43; H10D 30/6735; H10D 30/6757; H10D 62/121; H10D 64/017; H10D 64/258

(57) ABSTRACT

A method for manufacturing a semiconductor structure includes: forming a nanosheet stack on each of a first and second fins that are spaced apart in a first direction; forming dummy gate structures that are spaced apart in a second direction (each of which including a dummy gate and two gate spacers); forming source/drain (S/D) portions, such that the nanosheet stack is patterned into stack portions; forming active gates, each of which replaces the dummy gate of a corresponding dummy gate structure and sacrificial features of a corresponding stack portion; and forming S/D isolation features such that each of the S/D isolation features extends between two adjacent active gates without penetrating therethrough in the second direction, and such that each of the S/D portions on the first fin is spaced apart from a respective S/D portion on the second fin in the first direction by a respective S/D isolation feature.

### BACKGROUND

In order to meet the requirement of miniaturization of semiconductor device, spacing scaling among source/drain portions is being aggressively reduced. New approaches are required to ensure excellent performance and high production yield of semiconductor device, while keeping the spacing of source/drain portions of the semiconductor device small.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 33 are schematic views illustrating intermediate stages of the method for manufacturing the semiconductor structure in accordance with some embodiments as depicted in FIG. 1.

FIG. 34 is a flow diagram illustrating a method for manufacturing a semiconductor structure in accordance with some embodiments.

FIGS. 35 to 42 are schematic views illustrating intermediate stages of the method for manufacturing a semiconductor structure in accordance with some embodiments as depicted in FIG. 34.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects±10%, in some aspects ±5%, in some aspects±2.5%, in some aspects±1%, in some aspects±0.5%, and in some aspects±0.1% from the specified amount, as such variations are appropriate to perform the disclosed methods or employ the disclosed compositions.

Source/drain portion(s) may refer to a source or a drain, individually or collectively dependent upon the context.

The present disclosure is directed to a semiconductor structure having source/drain (S/D) isolation features, and a method for manufacturing the same. The semiconductor structure includes a plurality of S/D portions that are formed by an epitaxy growth process. The S/D isolation features are each configured to isolate two adjacent ones of the S/D portions in a first direction, without penetrating through active gates of two adjacent ones of active gate structures in a second direction. In the method of the present disclosure, the S/D isolation features may be formed prior to, or after formation of the active gates. In addition, the S/D isolation features and gate isolation features (that are each configured to separate a corresponding one of the active gates into parts) may be formed together in a same process, or formed sequentially in different processes. By including the S/D isolation features in the semiconductor structure, physical and electrical isolation of two adjacent ones of the S/D portions (on different fins that are spaced apart from each other in the first direction) can be secured, so as to avoid short circuit due to direct contact of the two adjacent ones of the S/D portions, thereby improving production yield of the semiconductor structure.

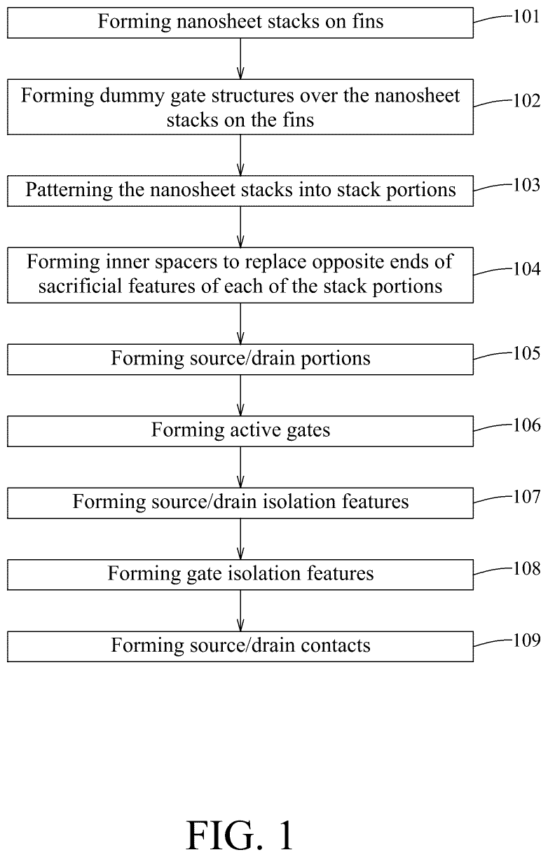

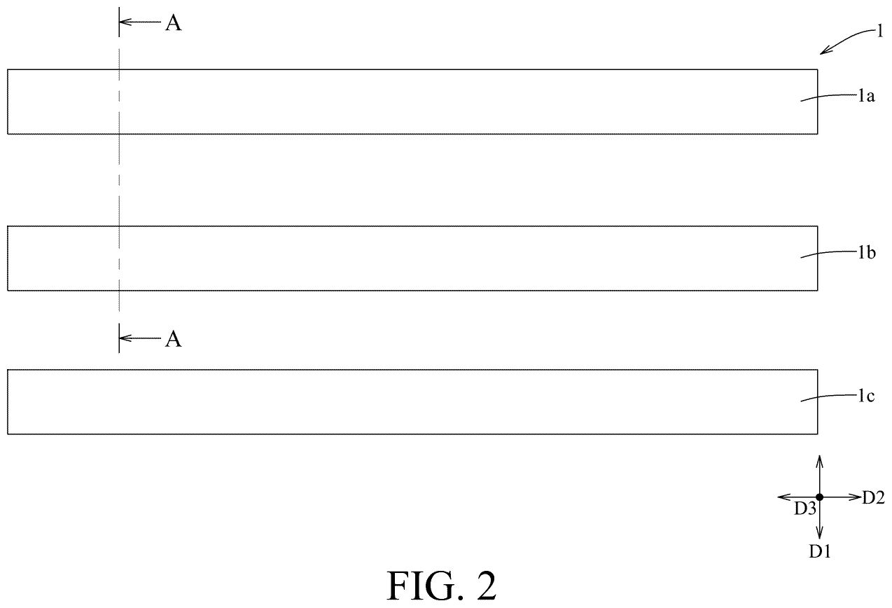

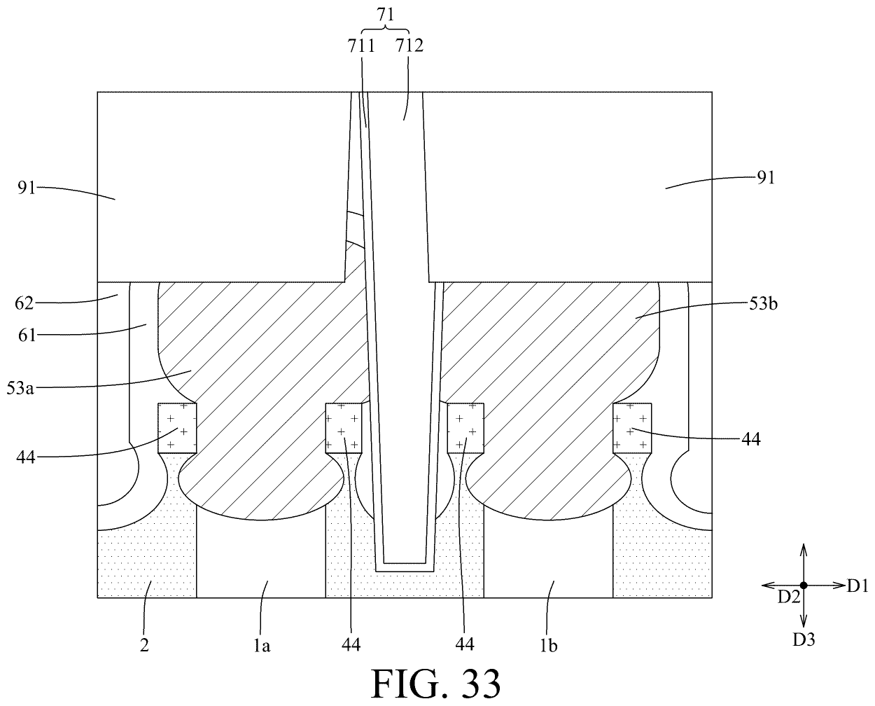

FIG. 1 is a flow diagram illustrating a method 100 for manufacturing the semiconductor structure (for example, the structure shown in FIG. 33) in accordance with some embodiments. FIGS. 2 to 33 illustrate schematic views of intermediate stages of the method 100 in accordance with some embodiments. Some repeating structures are omitted in FIGS. 2 to 33 for the sake of brevity. Additional steps can be provided before, after or during the method 100, and some of the steps described herein may be replaced by other steps or be eliminated. Please also note that hereinafter, some of the elements described are not shown in the figures for the sake of easy brevity.

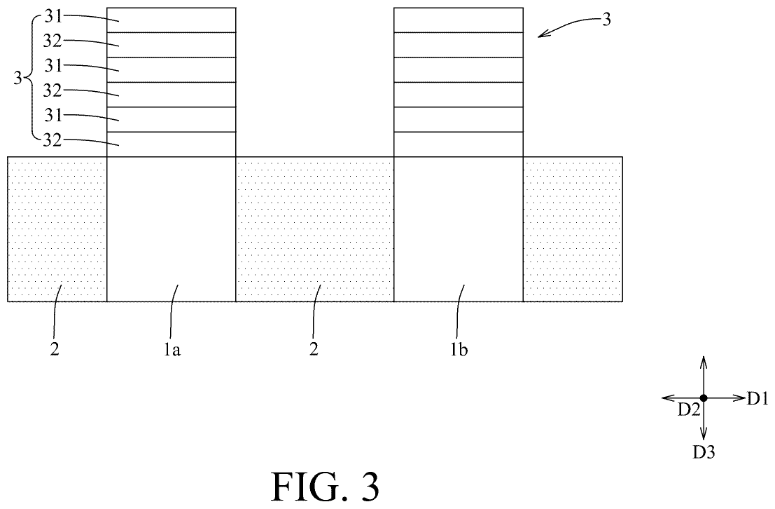

Referring to FIG. 1 and the example illustrated in FIGS. 2 and 3, the method 100 begins at step 101, where nanosheet stacks 3 are respectively formed on fins 1a, 1b, 1c of a substrate 1. FIG. 2 is a top view of an intermediate structure after performing step 101 (some of the elements are not shown), while FIG. 3 is a cross-sectional view of the intermediate structure along a line A-A shown in FIG. 2.

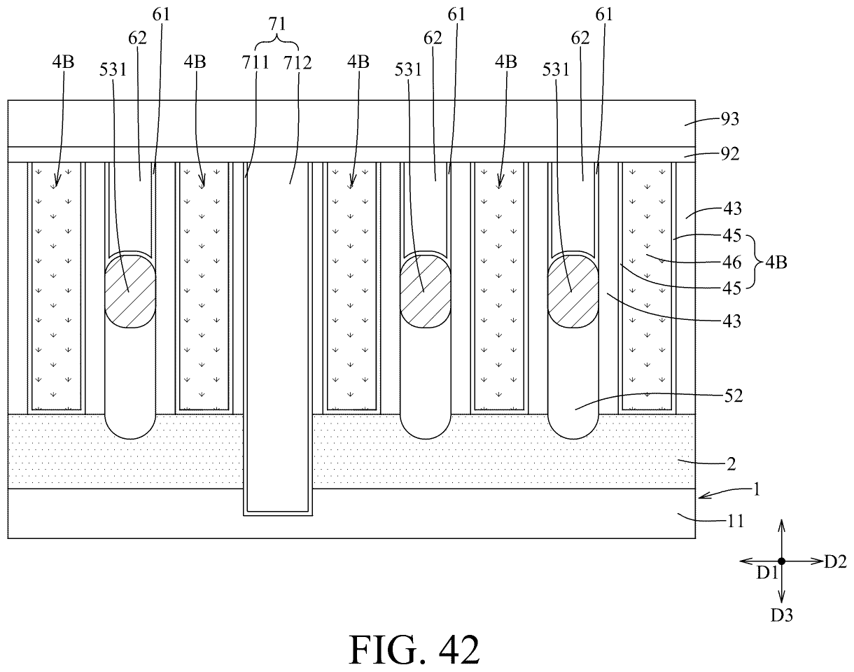

The substrate 1 includes a base 11 (see FIG. 42), and the fins 1a, 1b, 1c disposed on the base 11. The fins 1a, 1b, 1c are spaced apart from each other in a first direction D1. Number of fins may be determined according to practical needs. Exemplarily shown in FIG. 2, there are three of the fins 1a, 1b, 1c, but are not limited thereto. The three fins 1a, 1b, 1c are respectively known as a first fin 1a, a second fin 1b, and a third fin 1c. Please note that only the fins 1a, 1b, 1c are shown in the top view of FIG. 2, and the base 11 is omitted. The substrate 1 may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The substrate I may be doped with p-type impurities or n-type impurities, or undoped. In addition, the substrate 1 may be a bulk silicon substrate, a silicon-on-insulator (SOI) substrate, or a germanium-on-insulator (GOI) substrate. In the substrate 1, the base 11 may be made of a material that is the same or different from a material of the fins 1a, 1b, 1c. Other suitable materials for forming substrate 1 are within the contemplated scope of disclosure.

The nanosheet stacks 3 are not shown in FIG. 2. Referring to FIG. 3, each of the nanosheet stacks 3 is formed on a corresponding one of the fins 1a, 1b, 1c, and extends along a second direction (D2). In addition, each of the nanosheet stacks 3 includes first nanosheet layers 31 and second nanosheet layers 32 that are alternately stacked on each other along a third direction D3. The first, second and third directions D1, D2, D3 are transverse to, e.g., perpendicular to each other. There are three of the first nanosheet layers 31, and three of the second nanosheet layers 32, but are not limited thereto. In some embodiments, the first nanosheet layers 31 are made of silicon and are in step 103 further patterned into channels of the semiconductor structure, while the second nanosheet layers 32 are made of silicon germanium and are in step 103 further patterned into sacrificial features that are to be removed in subsequent steps 104 and 106. Other suitable materials and/or configurations for the first and second nanosheet layers 31, 32 are within the contemplated scope of the present disclosure.

In some embodiments, step 101 also includes forming isolation elements 2, each of which is disposed on the base and among the fins 1a, 1b, 1c (the isolation elements 2 are not shown in FIG. 2). The isolation elements 2 are also known as shallow trench isolation (STI) elements. The isolation elements 2 may include silicon oxide, or the like, but is not limited thereto.

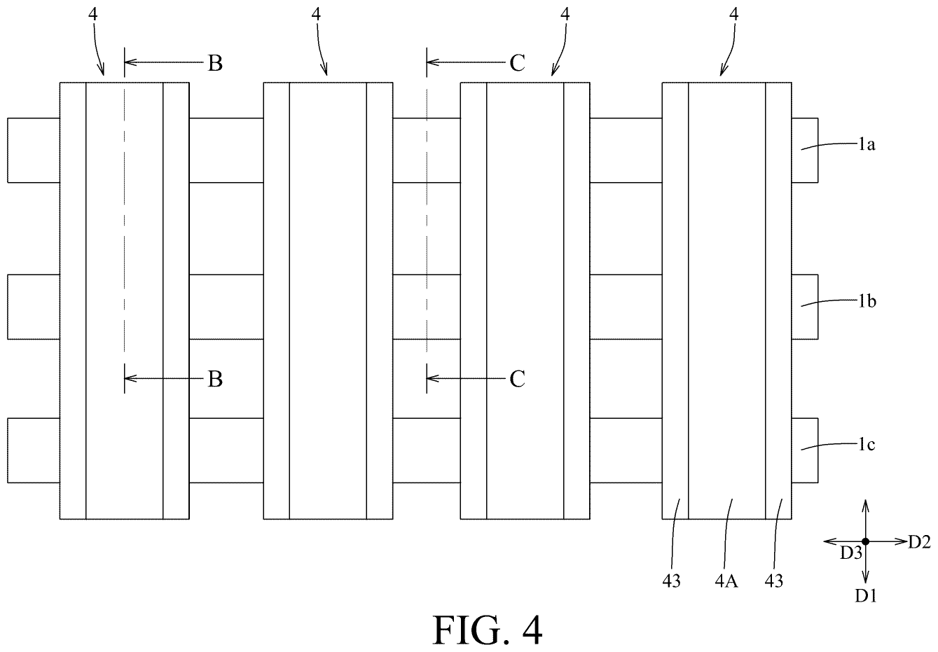

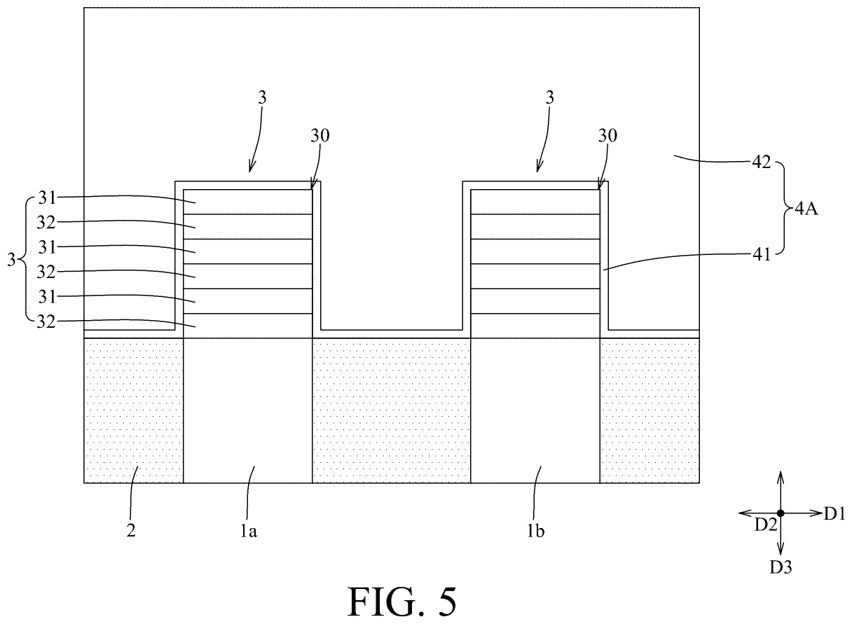

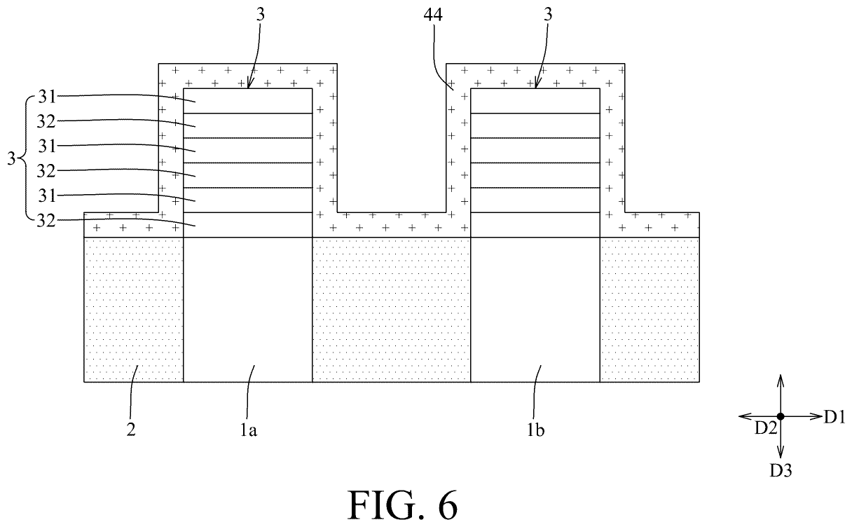

Referring to FIG. 1 and the example illustrated in FIGS. 4 to 6, the method 100 proceeds to step 102, where dummy gate structures 4 are formed over the nanosheet stacks 3 on the fins 1a, 1b, 1c. FIG. 4 is a top view of an intermediate structure after performing step 102 (some of the elements are not shown), while FIG. 5 and FIG. 6 are cross-sectional views of the intermediate structure respectively along lines B-B (at which one of the dummy gate structures 4 is formed) and C-C (at which the dummy gate structures 4 are not formed) shown in FIG. 4.

The dummy gate structures 4 are spaced apart from each other in the second direction D2. Each of the dummy gate structures 4 includes a dummy gate 4A, and two gate spacers 43 (see FIG. 4) formed at two opposite sides of the dummy gate 4A in the second direction D2. In some embodiments, step 102 also includes forming fin sidewalls 44 over the nanosheet stacks 3 and the isolation elements 2 that are exposed from the dummy gate structures 4 (see FIGS. 4 and 6). In FIG. 4, only the fins 1a, 1b, 1c, and the dummy gate 4A and the gate spacers 43 of each of the dummy gate structures 4 are shown. In some embodiments, the dummy gate 4A includes a dummy dielectric 41 (see FIG. 5) and a dummy gate electrode 42 formed on the dummy dielectric 41. The dummy dielectric 41 may include silicon oxide, but is not limited thereto. The dummy gate electrode 42 may include poly silicon, but is not limited thereto. The gate spacers 43 and the fin sidewalls 44 may include a silicon carbon-containing dielectric material, a silicon oxide-containing material, silicon nitride, other suitable materials, or combinations thereof. Other suitable materials and/or configurations for the dummy dielectric 41, the dummy gate electrode 42 and the gate spacers 43 are within the contemplated scope of the present disclosure.

In some embodiments, step 102 may include: sequentially depositing a dummy dielectric material layer (not shown, for forming the dummy dielectric 41) and a dummy gate material layer (not shown, for forming the dummy gate electrode 42) over the nanosheet stacks 3 and the isolation elements 2; performing a patterning process to form the dummy dielectrics 41 and the dummy gate electrodes 42 of the dummy gate structures 4; depositing a gate spacer material layer (not shown, for forming the gate spacers 43 and the fin sidewalls 44) over the dummy dielectrics 41, the dummy gate electrodes 42, the nanosheet stacks 3 and the isolation elements 2; and performing a selective etching process to form the gate spacers 43 of the dummy gate structures 4, and the fin sidewalls 44. The above depositions may involve any suitable deposition method, such as chemical vapor deposition (CVD), atomic layered deposition (ALD), physical vapor deposition (PVD), or other suitable processes.

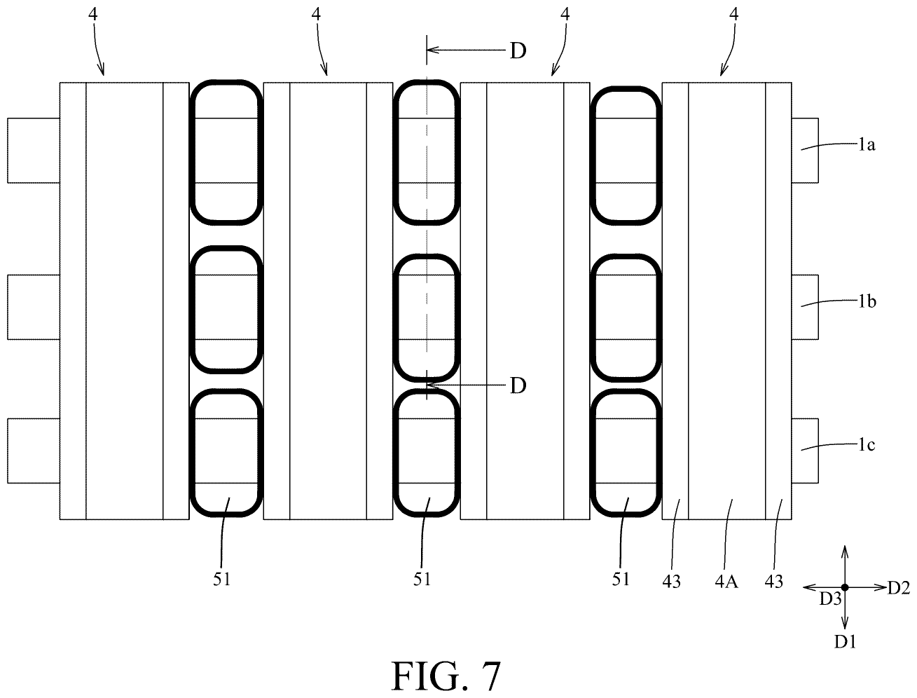

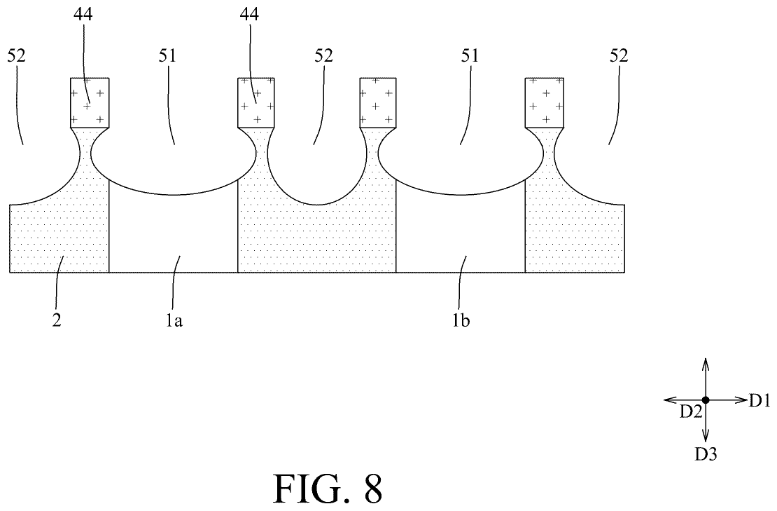

Referring to FIG. 1 and the example illustrated in FIGS. 7 to 8, the method 100 proceeds to step 103, where the nanosheet stacks 3 (see FIGS. 5 and 6) are patterned to form source/drain (S/D) recesses 51 on each of the fins 1a, 1b, 1c. FIG. 7 is a top view of an intermediate structure after performing step 103 (some of the elements are not shown), while FIG. 8 is a cross-sectional view of the intermediate structure along line D-D (at which the S/D recesses 51 are formed) shown in FIG. 7.

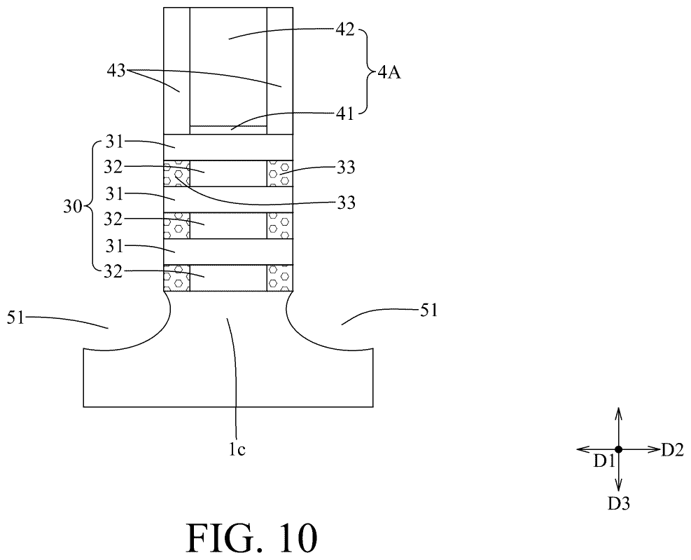

Specifically, each of the nanosheet stacks 3 on the fins 1a, 1b, 1c has portions (see FIG. 5) that are covered by the dummy gate structures 4, and another portions (see FIG. 6) that are exposed from the gate structures 4. The nanosheet stacks 3 are patterned to remove the another portions that are exposed from the gate structures 4 to form the S/D recesses 51, while the portions that are covered by the dummy gate structures 4 remain to serve as stack portions 30 (which are also shown in FIG. 5, and which have configurations shown in FIG. 10 after the subsequent step 104). That is, the nanosheet stacks 3 are each patterned into the stack portions 30 (respectively covered by the dummy gate structures 4, see FIG. 7) that are spaced apart from each other by the S/D recesses 51 in the second direction D2. In some embodiments, as shown in FIG. 8, the fin sidewalls 44 are also patterned to remain lower portions thereof aside the S/D recesses 51 (the remained lower portions of the fin sidewalls in FIG. 8 are also denoted by numeral 44). In the first direction D1, each of the S/D recesses 51 on the first fin 1a is aligned with a respective one of the S/D recesses 51 on the second fin 1b, and a respective one of the S/D recesses 51 on the third fin 1c. Each of the stack portions 30 includes channels (which are formed by patterning the first nanosheet layers 31 and thus are also denoted by numeral 31) and sacrificial features (which are formed by patterning the second nanosheet layers 32 and thus are also denoted by numeral 32).

In certain embodiments, the isolation elements 2 may also be accidentally partially removed to form voids 52 which are located between the S/D recesses 51 on adjacent ones of the fins 1a, 1b, 1c in the first direction D1. For instance, as shown in FIG. 8, a middle one of the voids 52 is formed between the left S/D recess 51 on the first fin 1a, and the right S/D recess 51 on the second fin 1b.

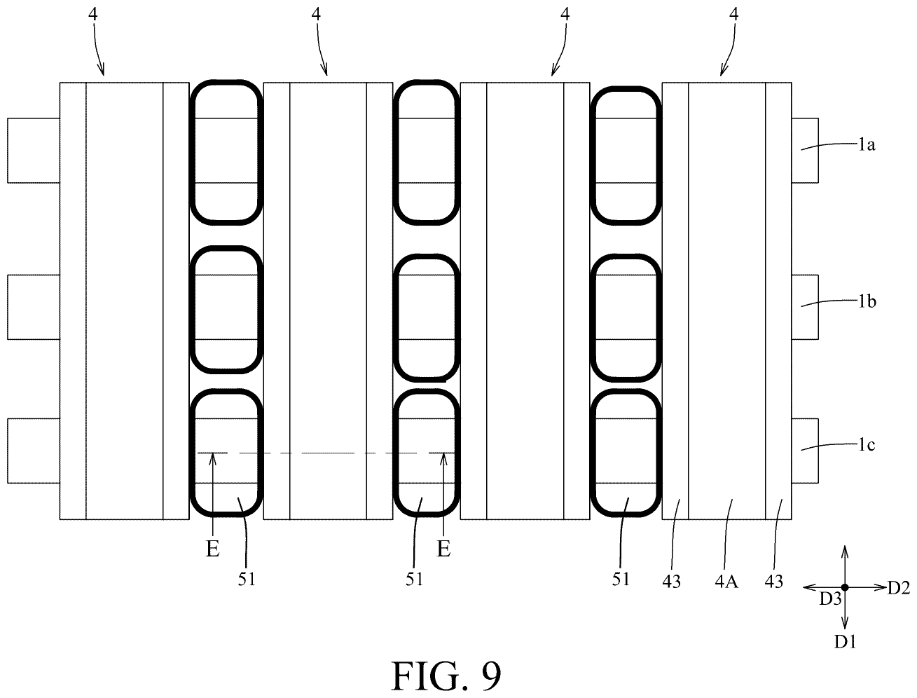

In some embodiments, step 103 may include: covering the dummy gate structures 4 with a protective mask; patterning the fin sidewalls 44 (see FIG. 6) to remove upper portions thereof, so as to expose the first and second nanosheet layers 31, 32 of the nanosheet stacks 3 underneath; and removing the first and second nanosheet layers 31, 32 of the nanosheet stacks 3 that are exposed from the dummy gate structures 4 to form the S/D recesses 51 (the bold lines shown in FIG. 7 respectively represent regions that are to be formed with S/D portions 53, see also FIG. 9), and the stack portions 30 (respectively covered by the dummy gate structures 4).

Referring to FIG. 1 and the example illustrated in FIGS. 9 to 10, the method 100 proceeds to step 104, where inner spacers 33 are formed to replace opposite ends of the second nanosheet layers 32 in each of the stack portions 30. FIG. 9 is a top view of an intermediate structure after performing step 104 (some of the elements are not shown), while FIG. 10 is a cross-sectional view of the intermediate structure respectively along line E-E (at which the inner spacers 33 of one of the stack portions 33 on the third fin 1c are formed) shown in FIG. 9.

Step 104 may include: removing opposite ends (in the second direction D2) of the sacrificial features 32 of each of the stack portions 30 to form lateral recesses (not shown) that are located underneath the gate spacers 43 of a corresponding one of the dummy gate structures 4 though adjacent ones of the S/D recesses 51; and forming the inner spacers 33 respectively in the lateral recesses using a suitable deposition process (such as CVD, ALD, PVD, or other suitable processes) and a suitable trimming process (such as dry etching or other suitable processes). In some embodiments, the inner spacers 33 may include a dielectric material such as silicon oxide, silicon nitride, silicon oxynitride, silicon carbide, or the likes, or combinations thereof. Other suitable materials and/or configurations for the inner spacers 33 are within the contemplated scope of the present disclosure.

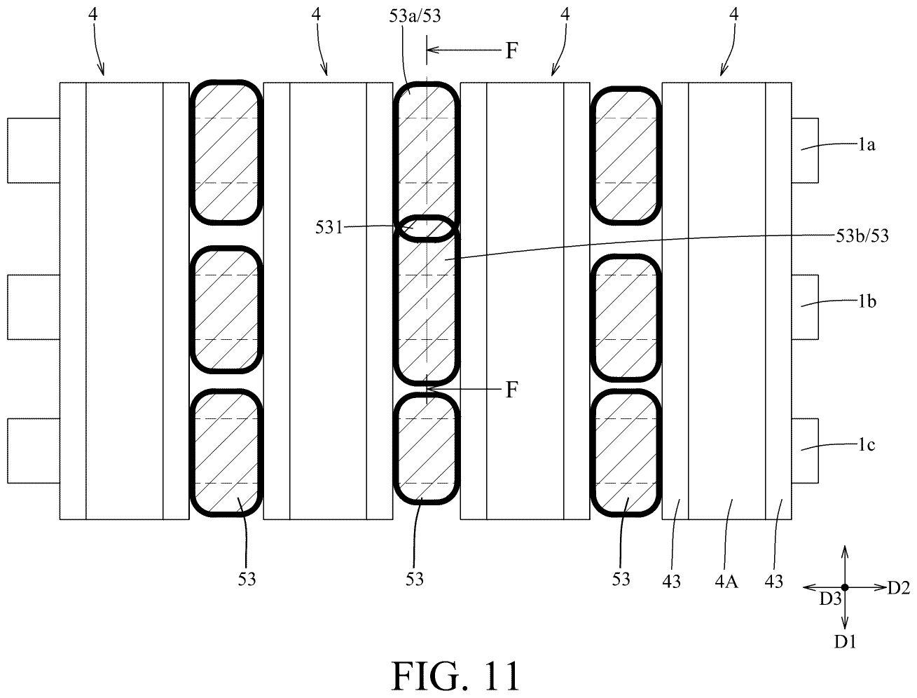

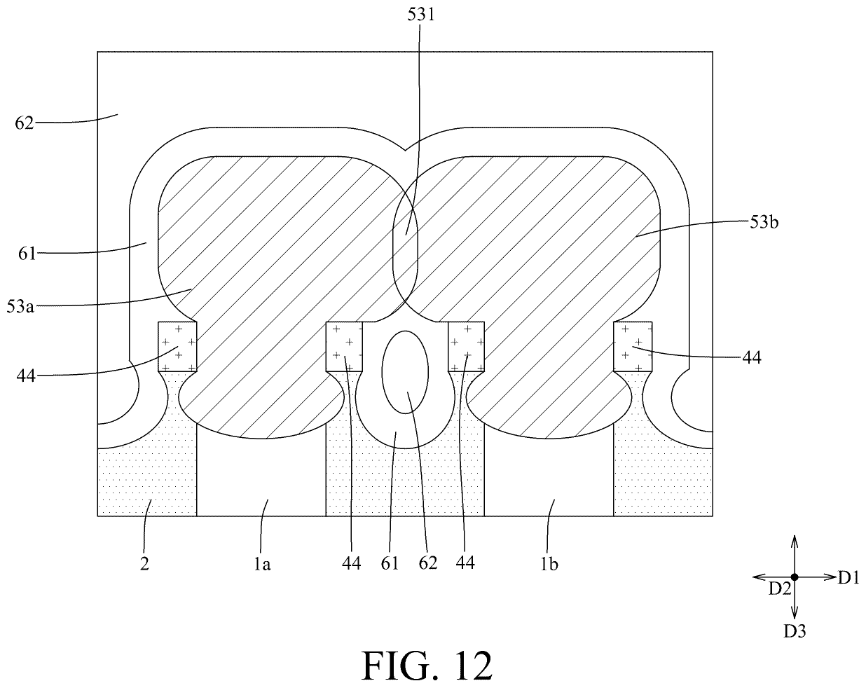

Referring to FIG. 1 and the example illustrated in FIGS. 11 to 12, the method 100 proceeds to step 105, where S/D portions 53 are formed on each of the fins 1a, 1b, 1c. FIG. 11 is a top view of an intermediate structure after performing step 105 (some of the elements are not shown), while FIG. 12 is a cross-sectional view of the intermediate structure along line F-F (at which one of the S/D portions 53a on the first fin 1a and one of the S/D portions 53b on the second fin 1b are formed) shown in FIG. 11.

Step 105 may include: forming the S/D portions 53 using an epitaxy growth process; forming a contact etch stop layer (CESL) 61 over the S/D portions 53; and forming an interlayer dielectric (ILD) 62 over the CESL 61. Please note that the CESL 61 and the ILD 62 are not shown in FIG. 11. The formation of the CESL 61 and the ILD 62 may involve deposition process (such as CVD, ALD, PVD, or other suitable processes) and a planarization process (such as chemical mechanical planarization (CMP) process or other suitable processes).

The S/D portions 53 are respectively formed in the S/D recesses 51 (see FIGS. 9 and 10), such that, on each of the fins 1a, 1b, 1c, the S/D portions 53 alternate with the stack portions 30 in the second direction D2. In the first direction D1, each of the S/D portions 53 on the first fin 1a is aligned with a corresponding one of the S/D portions 53 on the second fin 1b, and a corresponding one of the S/D portions 53 on the third fin 1c. In some embodiments, the aligned corresponding ones of the S/D portions 53 are spaced apart from each other by a predetermined distance, which could be small to meet the requirement of miniaturization of the semiconductor structure. However, in some cases, the aligned corresponding ones of the S/D portions 53 that are adjacent to each other accidentally and undesirably merge, to likely cause short circuit of the resultant semiconductor structure produced thereby. For instance, as shown in FIGS. 11 and 12, most of the S/D portions 53 are spaced apart from each other, except that one of the S/D portions denoted as 53a, which is formed on the first fin 1a, and another one of the S/D portions denoted as 53b, which is formed on the second fin 1b, merge to form a merging S/D region 531. It is noted that in some cases, when the lower portions of the fin sidewalls 44 remained is broken to expose a corresponding one of the fins 1a, 1b, c underneath, and materials for epitaxy growth of the S/D portions 53 may also grow outward of the fin sidewalls 44 (which is known as a bottom mushroom issue, which may also cause short circuit).

In certain embodiments, each of the S/D portions 53 may include multiple epitaxy layers, and may include silicon, silicon germanium, other suitable materials, or combinations thereof. In other embodiments, each of the S/D portions 53 may include any suitable dopants (such as n-type dopant(s), or p-type dopant(s)). Other suitable methods and/or processes for forming the S/D portions 53 are within the contemplated scope of the present disclosure.

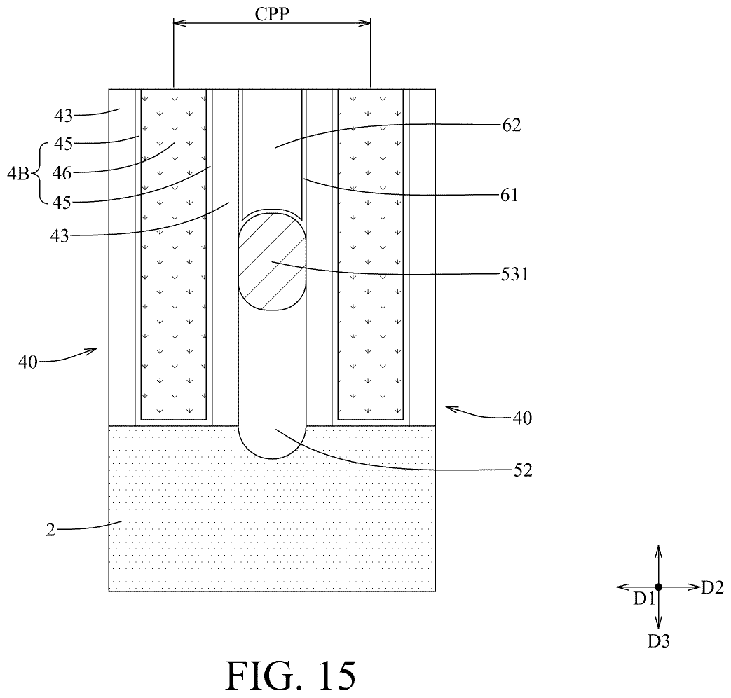

In the case that precursors for forming the CESL 61 and the ILD 62 diffuse through the merging S/D region 531 to reach and fill the void 52 therebeneath (see FIG. 8), the CESL 61 and the ILD 62 are also formed beneath the merging S/D region 531 (see FIG. 12). In the case that the precursors for forming the CESL 61 and the ILD 62 cannot diffuse through the merging S/D region 531 to reach the void 52 therebeneath, the void 52 (see FIG. 15) may remain after step 105. In certain embodiments, each of the CESL 61 and the ILD 62 may independently include a dielectric material such as silicon oxide, silicon nitride, or the like, or combinations thereof. Please note that the dielectric material of the CESL 61 is different from the dielectric material of the ILD 62. Other suitable materials for forming the CESL 61 and the ILD 62 are within the contemplated scope of the present disclosure.

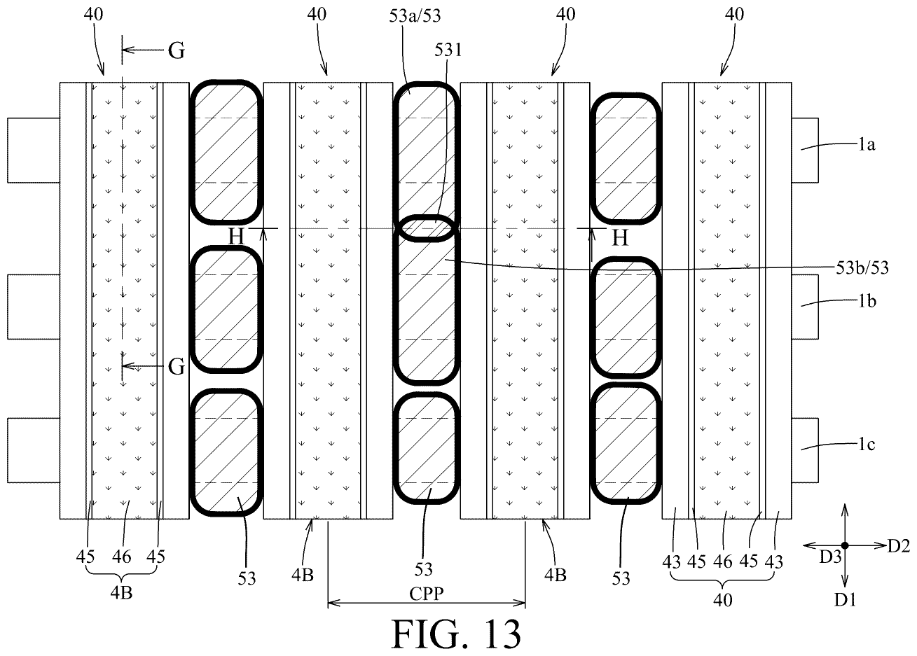

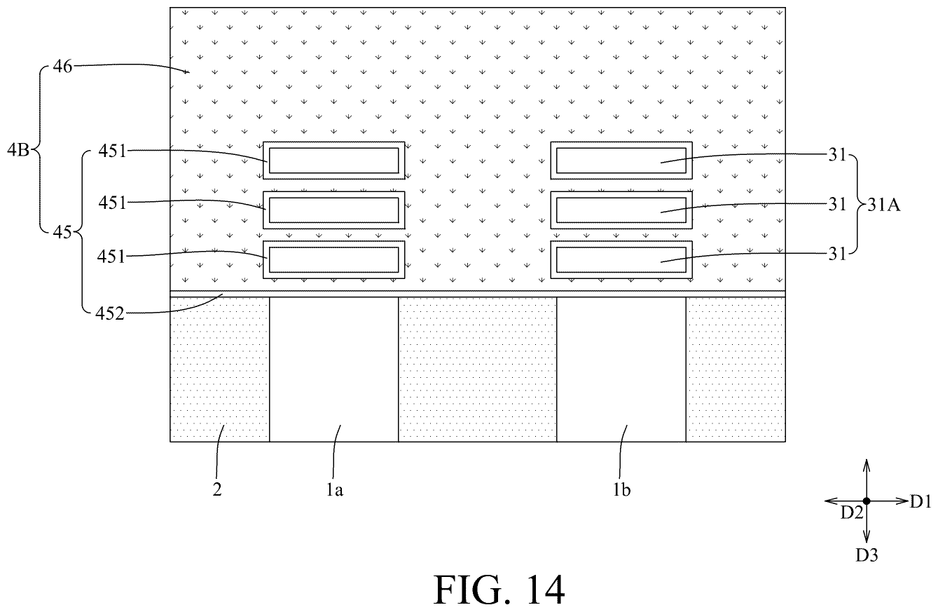

Referring to FIG. 1 and the example illustrated in FIGS. 13 to 15, the method 100 proceeds to step 106, where active gates 4B are each formed to replace the dummy gate 4A of a corresponding one of the dummy gate structures 4 (see FIGS. 5 and 10) and the sacrificial features 32 of a corresponding one of the stack portions 30 on each of the fins 1a, 1b, 1c (see FIGS. 9 and 10). FIG. 13 is a top view of an intermediate structure after performing step 106 (some of the elements, e.g., the CESL 61 and the ILD 62, are not shown), while FIGS. 14 and 15 are cross-sectional views of the intermediate structure respectively along lines G-G (in the first direction D1, at which the active gates 4B are formed) and H-H (in the second direction D2, at which two of the active gates 4B are formed adjacent to the merging S/D region 531) shown in FIG. 13.

Step 106 may include: removing the dummy gates 4A (including the dummy gate electrodes 42 and the dummy dielectrics 41) of the dummy gate structures 4 (see FIGS. 5 and 10) so as to obtain upper cavities (not shown) that expose the stack portions 30 and the inner spacers 33 underneath; removing the sacrificial features 32 of each of the stack portions 30 so as to obtain lower cavities (not shown) which are respectively beneath the upper cavities; forming the active gates 4B each of which is formed in one of the upper cavities and a respective one of the lower cavities, so as to obtain active gate structures 40. Removal of the dummy gates 42, the dummy dielectrics 41 and the sacrificial features 32 may be performed using any suitable etching methods (such as dry etching, wet etching, and so on). After removing the sacrificial features 32, the stack portions 30 are respectively formed into channel parts 31A (see FIG. 14) each including the channels 31 that are not removed. On each of the fins 1a, 1b, 1c, the S/D portions 53 and the channel parts 31A alternate with each other in the second direction D2. On each of the fins 1a, 1b, 1c, the channels 31 of each of the channel parts 31A interconnect two adjacent ones of the S/D portions 53. In some embodiments, before forming the active gates 4B, the channels 31 of the channel parts 31A may be first subjected to a sheet trimming process.

Each of the active gate structures 40 includes one of the active gates 4B and the two gate spacers 43 of a corresponding one of the dummy gate structures 4 (see FIG. 4). In some embodiments, each of the active gates 4B includes a gate dielectric 45 and an active gate electrode 46. The gate dielectric 45 includes first portions 451 that respectively surround the channels 31 of a corresponding ones of the channel parts 31A, and a second portion 452 that is conformally formed over the fins 1a, 1b, c, adjacent ones of the isolation elements 2, and the gate spacers 43. In some embodiments, the gate dielectric 45 includes a high dielectric constant material (e.g., hafnium oxide), but is not limited thereto. The active gate electrode 46 includes a conductive material such as a metal, a metal-containing nitride, a metal-containing silicide, a metal-containing carbides, but are not limited thereto. Other suitable materials and/or processes for forming the gate dielectric 45 and the active gate electrode 46 are within the contemplated scope of the present disclosure. The active gates 4B of the active gate structures 40 are arranged in the second direction D2 by a contacted poly pitch (hereinafter referred to as CPP, see FIGS. 13 and 15), which is a distance measured between centers of the active gates 4B of two adjacent ones of the active gate structures 40 in the second direction D2.

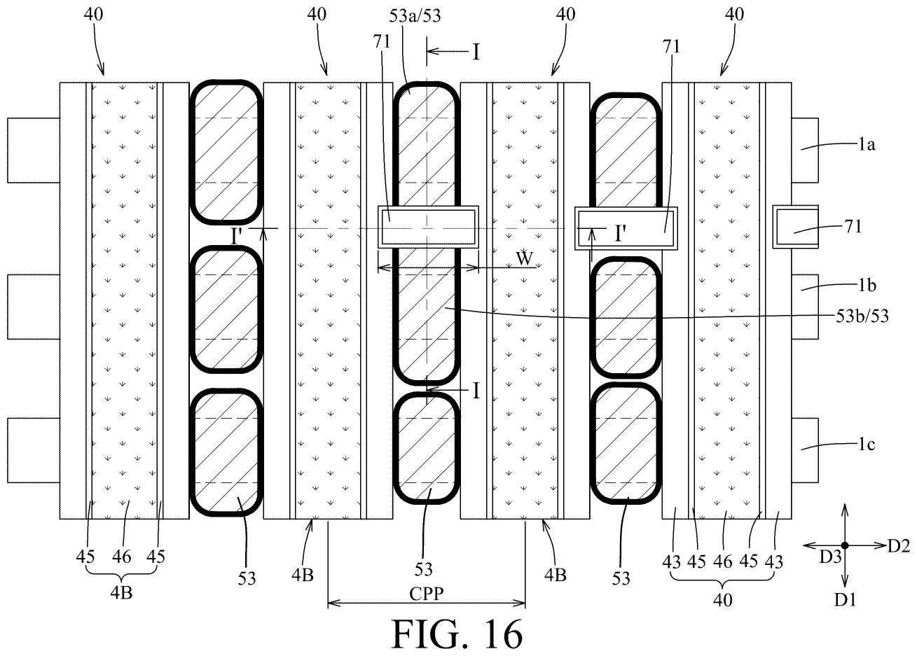

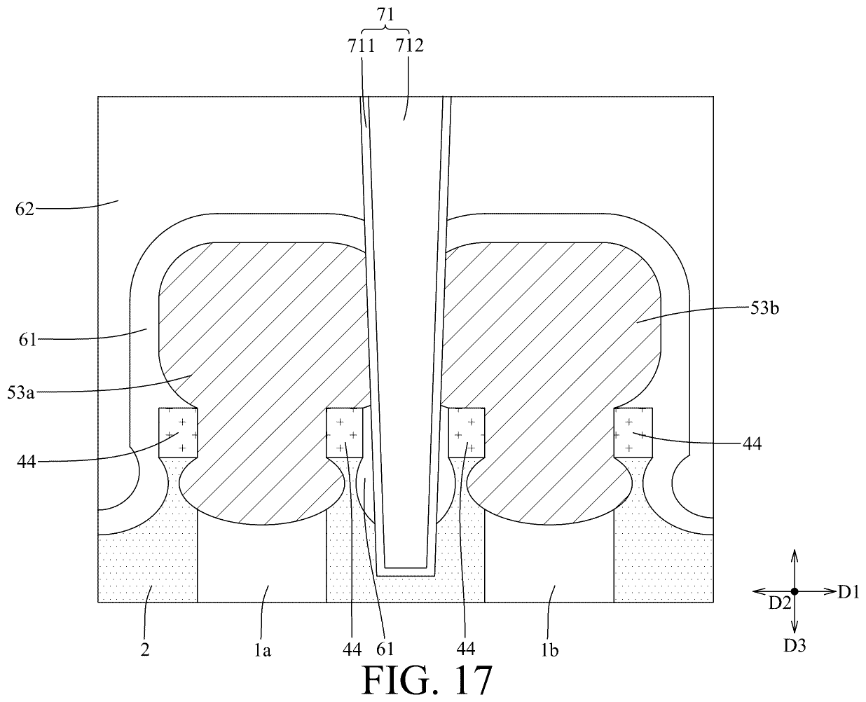

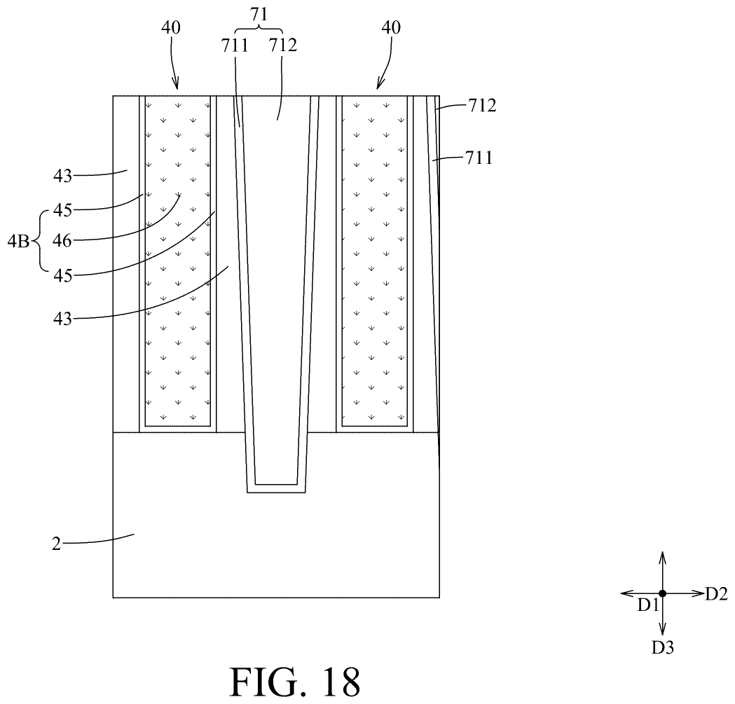

Referring to FIG. 1 and the example illustrated in FIGS. 16 to 18, the method 100 proceeds to step 107, where S/D isolation features 71 are each formed between two of the S/D portions 53 respectively on two adjacent ones of the fins 1a, 1b, 1c, and between two adjacent ones of the active gate structures 40 that sandwich the two of the S/D portions 53. FIG. 16 is a top view of an intermediate structure after performing step 107 (some of the elements are not shown), while FIGS. 17 and 18 are cross-sectional views of the intermediate structure respectively along line I-I (in the first direction D1, at which one of the S/D isolation features 71 is formed), and line I′-I′ (in the second direction D2, at which the one of the S/D isolation features 71 is formed) shown in FIG. 16.

In the first direction D1, the S/D isolation features 71 are each configured to isolate one of the S/D portions 53 on one of the fins 1a, 1b, 1c from a respective one of the S/D portions 53 on an adjacent one of the fins 1a, 1b, 1c. That is, each of the S/D portions 53 on one of the fins 1a, 1b, 1c is spaced apart from a respective one of the S/D portions 53 on an adjacent one of the fins 1a, 1b, 1c by a respective one of the S/D isolation features 71. For instance, as shown in FIGS. 16 and 17, the S/D portion 53a formed on the first fin 1a is isolated from and spaced apart from the S/D portion 53b formed on the adjacent second fin 1b by the leftmost isolation feature 71. In some embodiments, each of the S/D isolation features 71 is in direct contact with one of the S/D portions 53 on one of the fins 1a, 1b, c, and a respective one of the S/D portions on an adjacent one of the fins 1a, 1b, 1c. In other embodiments, each of the S/D isolation features 71 is spaced apart from the S/D portions 53.

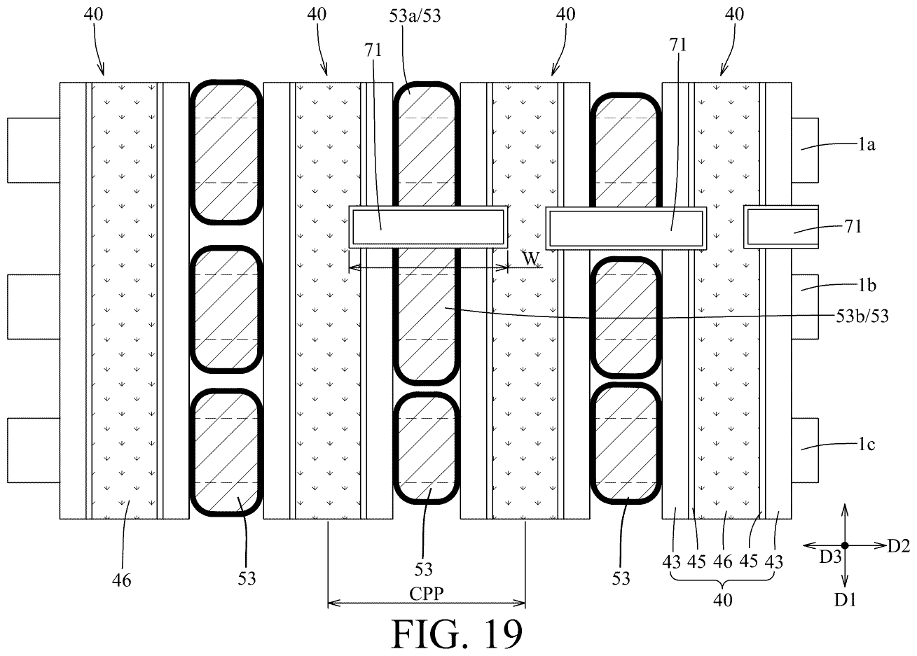

In the second direction D2, the S/D isolation features 71 each extends between two adjacent ones of the active gate structures 40. To be specific, each of the S/D isolation features 71 extends between the active gates 4B of two adjacent active gate structures 40, without penetrating through the active gates 4B of the two adjacent active gate structures 40. Each of the S/D isolation features 71 has two opposite ends in the second direction D2 that respectively face the two adjacent active gate structures 40. In some embodiments, the opposite ends of each of the S/D isolation features 71 do not penetrate into the two adjacent active gate structures 40. For instance, each of the two opposite ends may terminate at and is in direct contact with the CESL 61, or the ILD 62 located between the two adjacent active gate structures 40. In other embodiments, the opposite ends of each of the S/D isolation features 71 penetrate into the two adjacent active gate structures 40. It should be noted that, with respect to each of the S/D isolation features 71, each of the two adjacent active gate structures 40 includes a proximal one and a distal one of the two gate spacers 43. In some embodiments, each of the two opposite ends (of each of the S/D isolation features 71) terminates at the proximal one of the two gate spacers 43 in the corresponding one of the two adjacent active gate structures 40. As shown in FIGS. 16 and 18, the two opposite ends terminate at, and are in direct contact with the two proximal gate spacers 43, respectively, at the two adjacent active gate structures 40. In other embodiments, each of the two opposite ends penetrates through the proximal one of the two gate spacers 43, so as to penetrate into and terminate at the active gate 4B of the corresponding one of the two adjacent active gate structures 40. FIG. 19 is a top view of an intermediate structure which is similar to that of FIG. 16, but illustrates that the two opposite ends of each of the S/D isolation features 71 terminate at, and are in direct contact with the active gates 4B. It should be noted that, even though the one S/D isolation feature 71 extends into the active gates 4B of the two adjacent active gate structures 40 (and even extends into the active gate electrodes 46 of the two adjacent active gate structures 40), such active gate electrodes 46 remain physically and electrically continuous in the first direction D1, and surrounds the two opposite ends of the one S/D isolation feature 71, respectively. As such, resistance, or electrical conduction of the active gate electrodes 46 in the first direction (D1) is minimally affected, so as to ensure good performance of the semiconductor structure. In some other embodiments, each of the two opposite ends terminates at and is in direct contact with the gate dielectric 45 that is located between the active gate electrode 46 and the proximal one of the two gate spacers 43 in the corresponding one of the two adjacent active gate structures 40.

In certain embodiments, the S/D isolation features 71 may each have a width (W, see FIG. 16) measured in the second direction D2 that is less than the CPP. In some embodiments, the width (W) is adjusted according to materials of the active gate electrode 46. For instance, depending on the conductivity type of the semiconductor structure, different materials may be adopted in the active gate electrode 46 of the active gate structures 40 so as to adjust threshold voltage of the semiconductor structure. In the case that the semiconductor structure is determined to be an n-type device, the active gate electrode 46 of each of the active gate structures 40 may include aluminum, which is easily oxidized. In order to prevent the active gate electrodes 46 including aluminum from being oxidized, the S/D isolation features 71 among such active gate electrodes 46 may be formed with a relatively small width (W) (for example, the S/D isolation features 71 are prevented from being in contact with the active gate electrodes 46 including aluminum). In the case that the semiconductor structure is determined to be a p-type device, the S/D isolation features 71 thereof may be formed with a relatively large width (W).

In the third direction D3, the S/D features 71 each extends into and terminates at a corresponding one of the isolation elements 2 (see FIG. 18). In some embodiments, the S/D features 71 each extends through the corresponding isolation element 2 into and terminates at the base 11 of the substrate 1 (see FIG. 42).

The S/D isolation features 71 may include a dielectric material. Examples of the dielectric material are silicon nitride (SiN), silicon oxide (e.g., SiO₂), silicon oxynitride (SiON), silicon carbon nitride (SiCN), silicon carbon oxynitride (SiCON), silicon oxycarbide (SiCO), a high electric constant (high-K) material such as hafnium oxide (HfO), aluminum oxide (AlO), or the likes, or combinations thereof. Other suitable materials for the S/D isolation features 71 are within the contemplated scope of the present disclosure. In some embodiments, the dielectric material may have a dielectric constant lower than a dielectric constant of a dielectric material of each of the CESL 61, the gate spacers 43 and the inner spacers 33, so as to have a reduced capacitance of the semiconductor structure.

The S/D isolation features 71 may have a single layer structure, or a composite structure having multiple layers. For instance, each of the S/D isolation features 71 may have an outer region 711 that is made of a higher dielectric constant material, such as silicon nitride, but is not limited thereto, and an inner region 712 that is made of a lower dielectric constant material, such as silicon oxide, but is not limited thereto. The inner region 712 is surrounded by the outer region 711. In some embodiments, the outer region 711 is omitted. Other suitable configurations and materials of the S/D isolation features 71 are within the contemplated scope of the present disclosure.

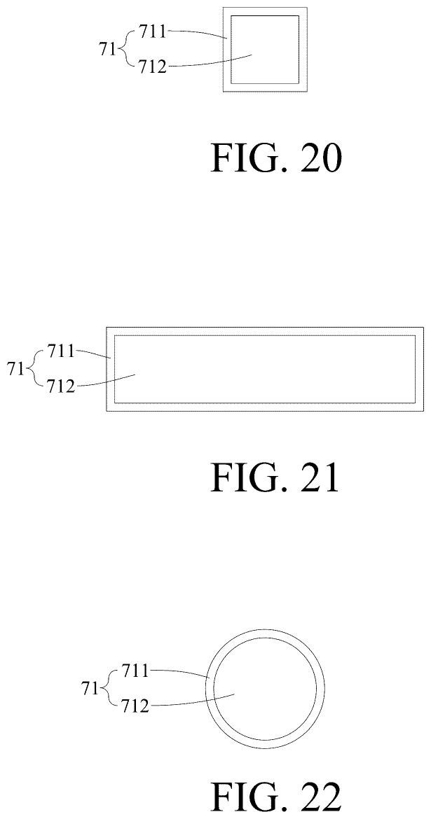

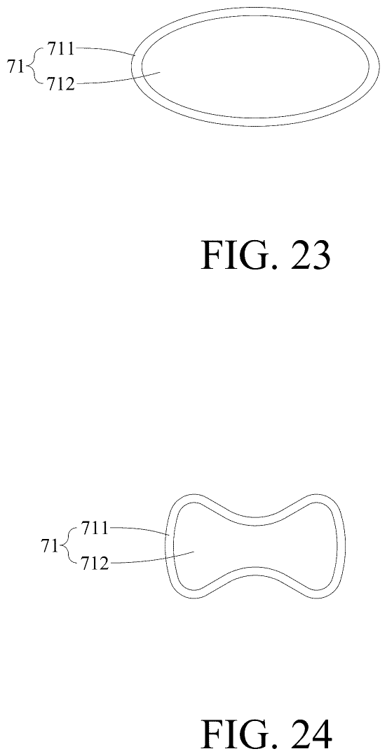

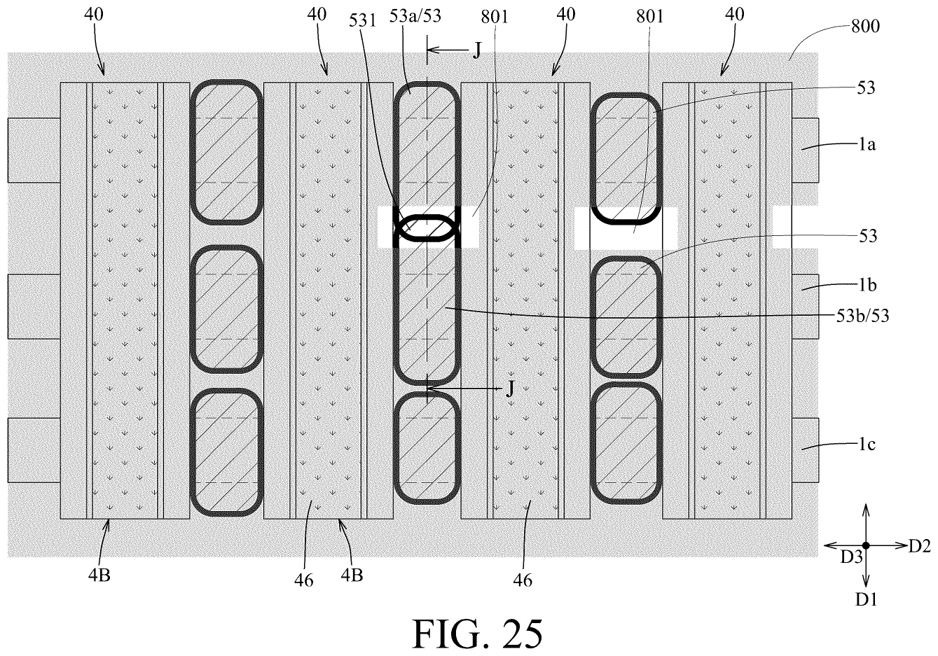

The S/D isolation features 71 may be formed into different shapes according to practical needs. For instance, from a top view of the S/D isolation features 71, each of the S/D isolation features 71 may have a shape of square (see FIG. 20), rectangle (see FIG. 21), circle (see FIG. 22), oval (see FIG. 23), dog-bone (see FIG. 24), or the likes, or combinations thereof. Other suitable shapes of the S/D isolation features 71 are within the contemplated scope of the present disclosure.

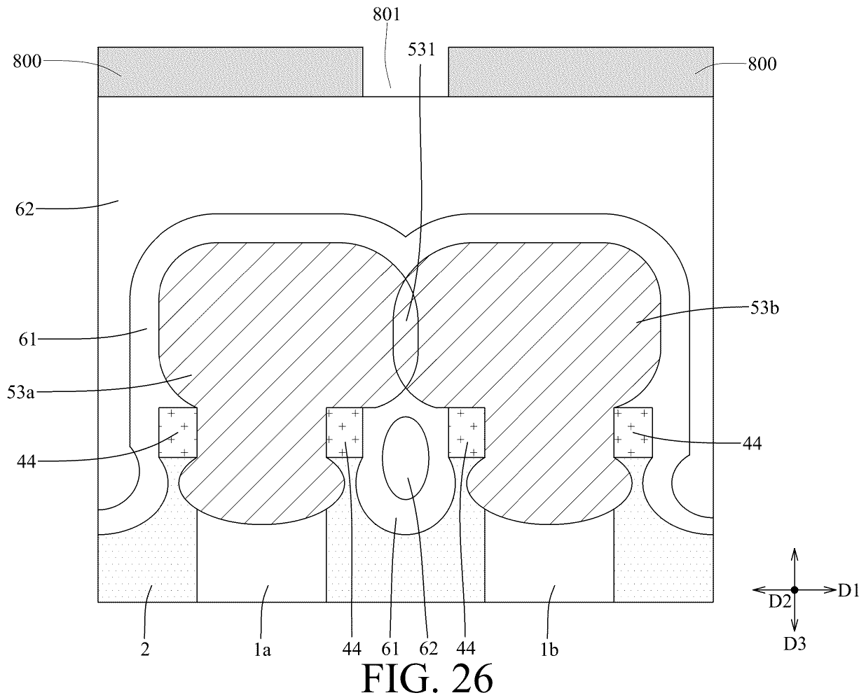

FIGS. 25 to 28 illustrates intermediate structures during formation of the S/D isolation features 71. Referring to FIGS. 25 and 26, the S/D isolation features 71 are formed by first forming a patterned mask 800 over the structure shown in FIG. 13. FIG. 25 is a top view of the intermediate structure after forming the patterned mask 800. FIG. 26 is a cross-sectional view of the intermediate structure along line J-J shown in FIG. 25. The patterned mask 800 has openings 801 that expose regions that are to be removed and for forming the S/D isolation features 71, i.e., regions each of which is located between two of the S/D portions 53 respectively on two adjacent ones of the fins 1a, 1b, 1c, and each of which is located between two adjacent ones of the active gates 4B. For instance, as shown in FIG. 25, the patterned mask 800 exposes an area in position corresponding to the merging S/D region 531 (the CESL 61 and the ILD 62 above is not drawn in FIG. 25), and an area in position corresponding to a region between the rightmost S/D portion 53 located on the first fin 1a and the rightmost S/D portion 53 located on the second fin 1b. As shown in FIG. 26, one of the openings 801 is located above the merging S/D region 531. The patterned mask 800 may be a hard mask include silicon nitride, or titanium nitride. In other embodiments, the patterned mask 800 may include silicon, yttrium, or silicon oxide. The patterned mask 800 may be formed using any suitable deposition method, such as chemical vapor deposition (CVD), atomic layered deposition (ALD), or physical vapor deposition (PVD), but are not limited thereto. Other suitable materials and methods for forming the patterned mask 800 are within the contemplated scope of the present disclosure.

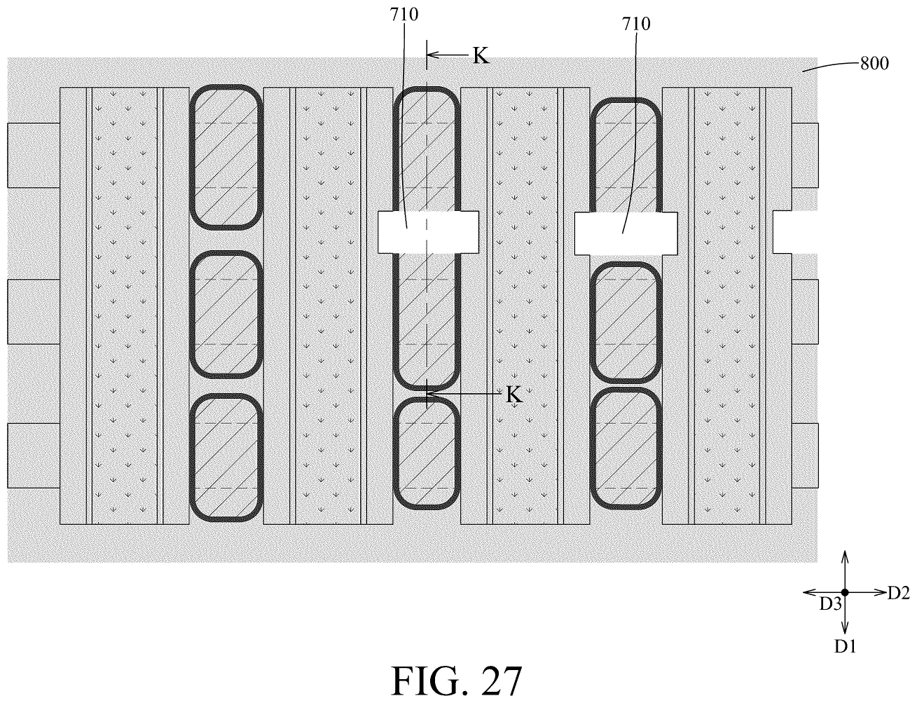

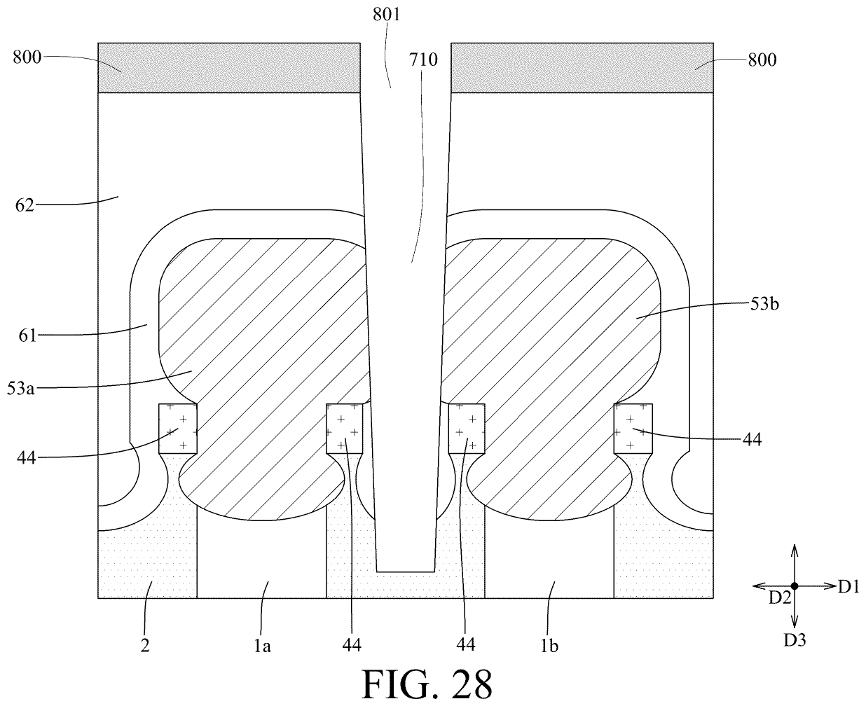

Referring to FIGS. 27 and 28, a removal process is performed to remove the elements that are exposed from the patterned mask 800 through the openings 801, so as to form cavities 710 that are to be filled with the S/D isolation features 71 (see FIGS. 16 to 17). FIG. 27 is a top view of an intermediate structure after forming the cavities 710, while FIG. 28 is a cross-sectional view of the intermediate structure along line K-K (at which the merging S/D region 531 is removed to form one of the cavities 710) shown in FIG. 27. As discussed with reference to FIGS. 16 to 18, and as shown in FIG. 28, each of the cavities 701 may penetrate, in the third direction D3, through the ILD 62, the CESL 61, the S/D portions 53 (e.g., the merging S/D region 531), the isolation element 2 (or even the base 11 of the substrate 1 (see FIG. 42)). In the second direction D2, each of the cavities 701 may extend into the gate spacers 43, the gate dielectric 45, or the active gate electrode 46 (without penetrating through the active gates 4B) of the two adjacent ones of the active gate structures 40. In some embodiments, the removal process may be an etching process, such as dry etching, but is not limited thereto. The etchant employed is capable to etch and remove the materials of each of the ILD 62, the CESL 61, the S/D portions 53, the isolation element 2, the gate spacers 43, the gate dielectric 45 and the active gate electrode 46. In some embodiments, the etchant may include a fluoride containing gas, a chlorine containing gas, a bromide containing gas, or an iodide containing gas, but is not limited thereto. Other suitable chemicals and methods for the removal process are within the contemplated scope of the present disclosure.

Referring back to FIGS. 16 and 17, the S/D isolation features 71 are formed in the cavities 710 (see FIGS. 27 and 28). Any suitable methods known in the art, such as any suitable deposition process, to first fill the cavities 710, followed by, e.g., a chemical mechanical planarization (CMP) process, to remove any excess materials of the S/D isolation features 71 and the patterned mask 800, but are not limited thereto. Other suitable methods for forming the S/D isolation features 71 are within the contemplated scope of the present disclosure. After forming the S/D isolation features 71, the patterned mask 800 may be removed using any suitable methods known in the art.

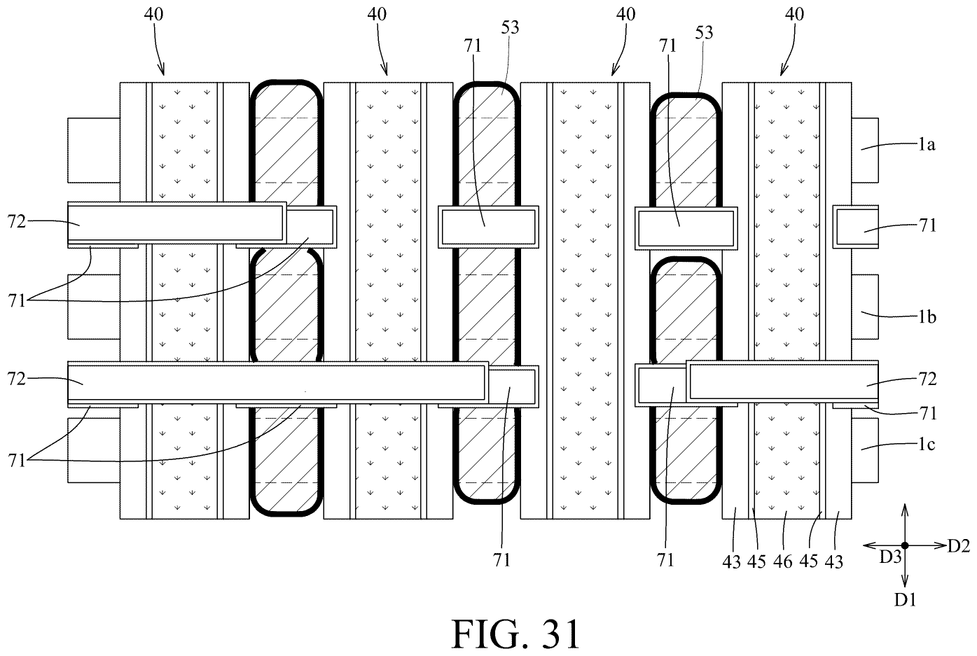

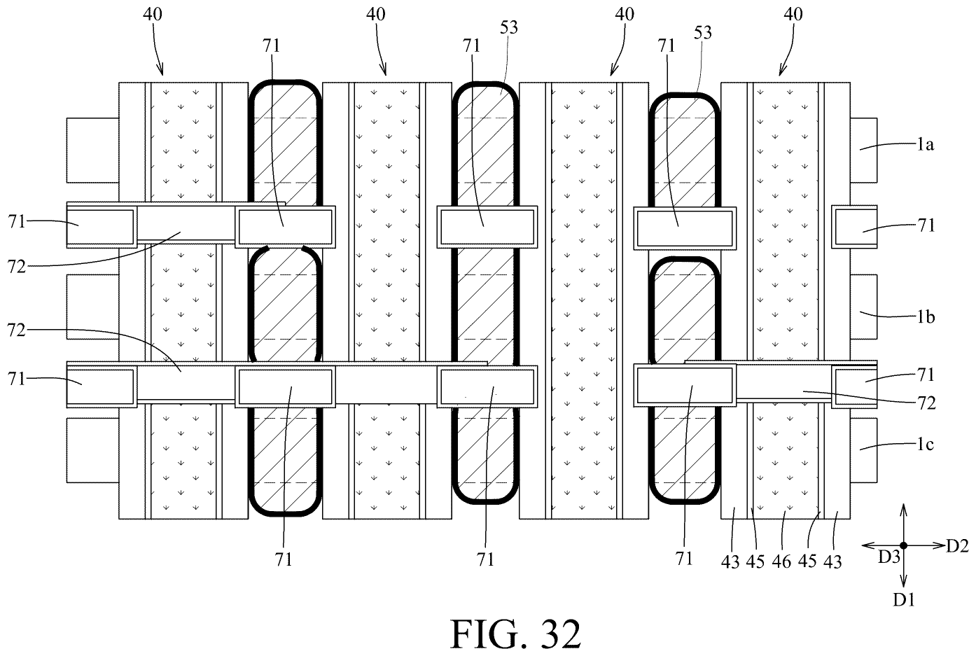

Please note that in the exemplary examples shown in FIGS. 16 to 18, three of the S/D isolation elements 71 are formed, but are not limited thereto. In other embodiments, the S/D isolation elements 71 as aforementioned are formed between every two adjacent ones of the S/D portions 53 in the first direction D1, regardless of whether any merging of the S/D portions 53 occurs or not (see FIGS. 31 and 32).

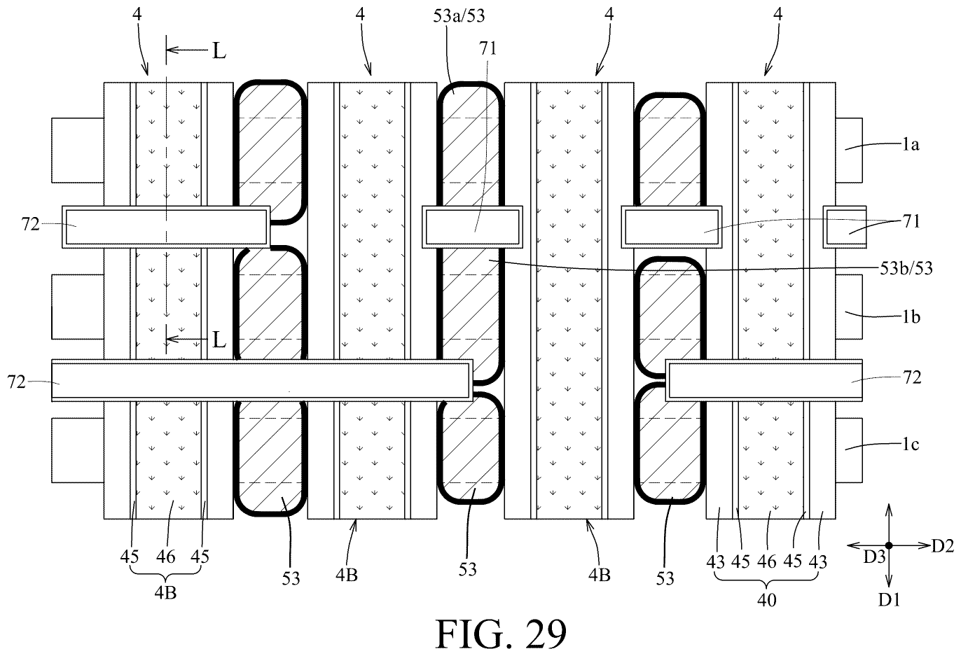

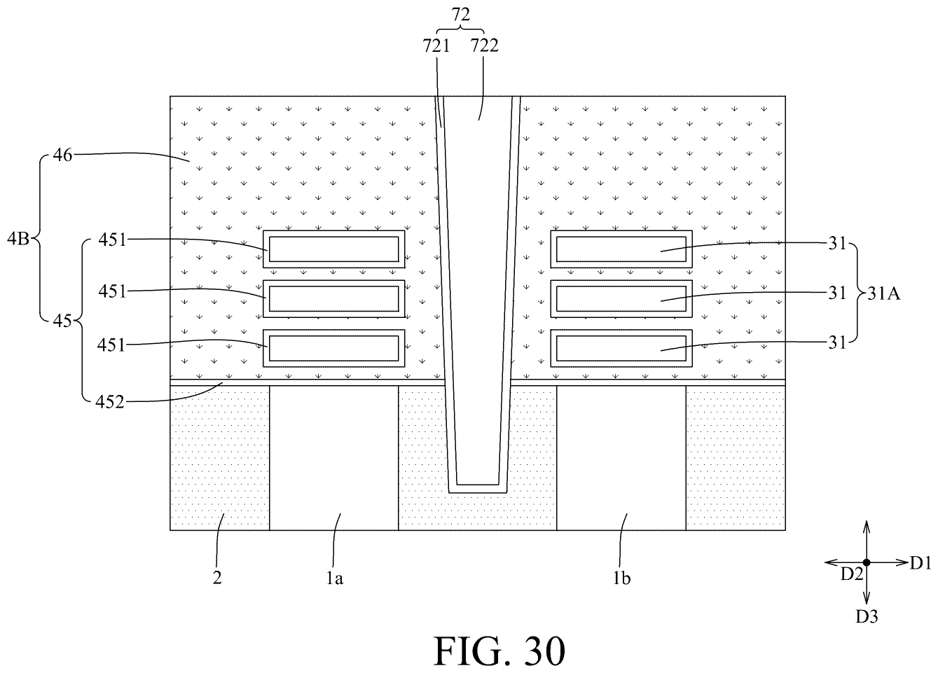

Referring to FIG. 1 and the example illustrated in FIGS. 29 to 30, the method 100 proceeds to step 108, where gate isolation features 72 are formed, each of which separates a corresponding one of the active gates 4B into two parts in the first direction D1. FIG. 29 is a top view of an intermediate structure after performing step 108 (some of the elements are not shown), while FIG. 30 is a cross-sectional view of the intermediate structure along line L-L (at which one of the gate isolation features 72 is formed) shown in FIG. 29.

Unlike the S/D isolation features 71 (which do not penetrate through the active gates 4B of the adjacent ones of the active gate structures 40), the gate isolation features 72 are each configured to penetrate through the active gate 4B (and the two gate spacers 43) of the corresponding active gate structure 40, so that each of the gate isolation features 72 divides the corresponding active gate structure 40, which is originally continuous in the first direction D1, (see FIG. 16), into two parts (see FIG. 29). In some embodiments, each of the active gate structures 40 is divided into more than two parts by having more than one of the gate isolation features 72 penetrating therethrough.

Specifically, each of the gate isolation features 72 penetrates through, in the second direction D2, the active gate electrode 46 of one (or more) of the active gate structures 40, i.e., the active gate electrode 46 of the one (or more) of the active gate structures 40 is formed into two discontinuous parts in the first direction D1 by a corresponding one of the gate isolation features 72. In some embodiments, each of the gate isolation features 72 may extend along the second direction D2, so as to penetrate through the active gate electrodes 46 and the gate spacers 43 of a corresponding one(s) of the active gate structures 40, as well as, but not necessarily, into an adjacent one(s) of the source/drain portions 53 in the second direction D2. For instance, as shown in FIG. 29, the gate isolation feature 72 located at the upper left corner merely penetrates through the leftmost one of the active gate 4B but does not penetrate through any of the source/drain portion 53. The gate isolation feature 72 located at the lower left corner penetrates through the two leftmost ones of the active gates 4B and the leftmost S/D portions 53 on the second fin 1b and on the third fin 1c, and terminates at a region between the middle S/D portions 53 on the second fin 1b and on the third fin 1c. In case that the middle S/D portions 53 on the second fin 1b and on the third fin 1c are merged, such gate isolation feature 72 may not be able to isolate such merged S/D portions 53. Therefore, the S/D isolation features 71 are vital to ensure that adjacent ones of the S/D portions 53 in the first direction D1 are isolated from each other, so as to prevent merging, or bottom mushroom issue thereof, thereby preventing short circuit of the semiconductor structure, while permitting the gate isolation features 72 to be configured to divide the active gate 4B into two parts, according to practical needs.

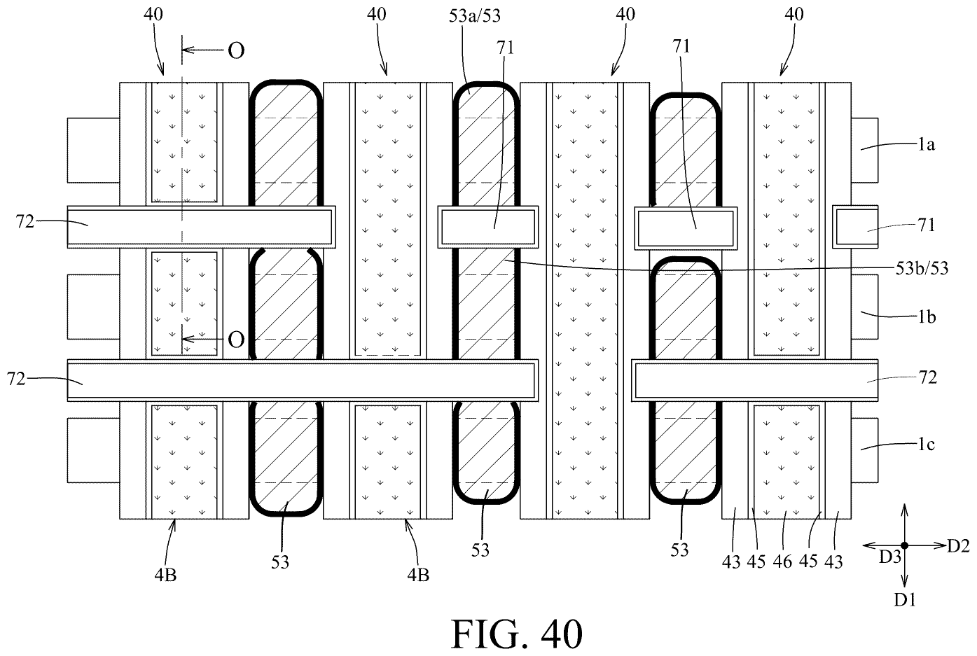

In some embodiments, two opposite ends of each of the gate isolation features 72 may each terminate in two of the source/drain portions 53 respectively on two adjacent ones of the fins 1a, 1b, 1c, as shown in FIG. 29. In other embodiments, the two opposite ends of each of the gate isolation features 72 may each terminate in one of the gate spacers 43 of a corresponding one of the active gate structures 40 as shown in FIG. 40. Termination of each of the two opposite ends of each of the gate isolation features 72 may be determined according to practical needs, as long as the desired active gate(s) 4B is (are) divided into parts in the first direction D1.

Material and method for forming the gate isolation features 72 are similar to those of the S/D isolation features 71 with reference to FIGS. 16 to 28, and details thereof are omitted for the sake of brevity. In some embodiments, a material of the S/D isolation features 71 is the same as a material of the gate isolation features 72. In other embodiments, the material of the S/D isolation features 71 is different from the material of the gate isolation features 72.

In some embodiments, both the S/D isolation features 71 and the gate isolation features 72 are formed together in a same process, i.e., steps 107 and 108 are performed together using the same patterned mask (which is beneficial to save cost for making additional patterned mask(s)). Referring back to FIG. 25, the patterned mask 800 may also have another openings (not shown) exposing regions that are to be removed for forming the gate isolation features 72 in addition to the openings 801 for forming the S/D isolation features 71.

In other embodiments, the S/D isolation features 71 and the gate isolation features 72 are formed sequentially in different processes (either forming the S/D isolation features 71 first, or forming the gate isolation features 72 first, is adequate, and can be determined based on practical needs). Referring to FIG. 31, in certain embodiments, wherein the gate isolation features 72 are formed after forming the S/D isolation features 71, one(s) of the gate isolation features is (are) formed to penetrate into a corresponding one(s) of the S/D isolation features 71. Vice versa, referring to FIG. 32, in some other embodiments, the S/D isolation features 71 are formed after forming the gate isolation features 72, one(s) of the S/D isolation features 71 is (are) formed to penetrate into a corresponding one(s) of the gate isolation features 72. From FIGS. 31 and 32, in some embodiments, the S/D isolation features 71 are each formed between two adjacent ones of the S/D portions 53 on two adjacent ones of the fins 1a, 1b, 1c. In other embodiments, when two adjacent S/D portions 53 respectively on adjacent ones of the fins 1a, 1b, 1c are already isolated from each other by one of the gate isolation features 72, the S/D isolation features 71 therebetween may be omitted.

Referring to FIG. 1 and the example illustrated in FIG. 33, the method 100 proceeds to step 109, where S/D contacts 91 are formed penetrating into, and in direct contact with the S/D portions 53, respectively. FIG. 33 is a cross-sectional view of the intermediate structure in the first direction D1 after performing step 109.

Specifically, each of the S/D contacts 91 extends through the ILD 62, the CESL 61, and a corresponding one of the S/D isolation features 71 so as to reach a corresponding one of the S/D portions 53.

In some embodiments, step 109 includes: forming a patterned mask (not shown) over the structure shown in FIG. 29 to expose regions that are to be removed and formed with the S/D contacts 91; performing a removal process, such as an etching process, but is not limited thereto, to remove portions of the ILD 62 and the CESL 61 so as to expose the S/D portions 53 underneath; filling a material for forming the S/D contacts 91; and removing an excess amount of the material, thereby forming the S/D contacts 91. In some embodiments, the material for forming the S/D contacts 91 is a conductive material, such as copper, tungsten, cobalt, ruthenium, aluminum, palladium, nickel, platinum, a low resistivity metal constituent, or the like, or combinations thereof, but is not limited thereto. Other suitable materials and/or configurations for forming the S/D contacts 91 are within the contemplated scope of the present disclosure.

After completing step 109, the semiconductor structure is obtained. The semiconductor structure includes, on each of the fins 1a, 1b, 1c (that are spaced apart form each other in the first direction D1), the S/D portions 53 (see FIG. 33) and the channel parts 31A (see FIG. 30) that alternate with the S/D portions 53 in the second direction D2. The semiconductor structure also includes the active gate structures 40 that are spaced apart from each other in the second direction D2 and that are respectively disposed on and around the channels 31 of a corresponding one of the channel parts 31A on each of the fins 1a, 1b, 1c. Each of the active gate structures 40 includes one of the active gates 4B, and two of the gate spacers 43 at opposite sides of the one of the active gates 4B in the second direction D2. The semiconductor structure also includes the S/D isolation features 71, each of which isolates one of the S/D portions 53 on one of the fins 1a, 1b, 1c and a respective one of the S/D portions 53 on an adjacent one of the fins 1a, 1b, 1c in the first direction D1, and which is prevented from extending through the active gates 4B of two adjacent ones of the active gate strictures 40 in the second direction D2.

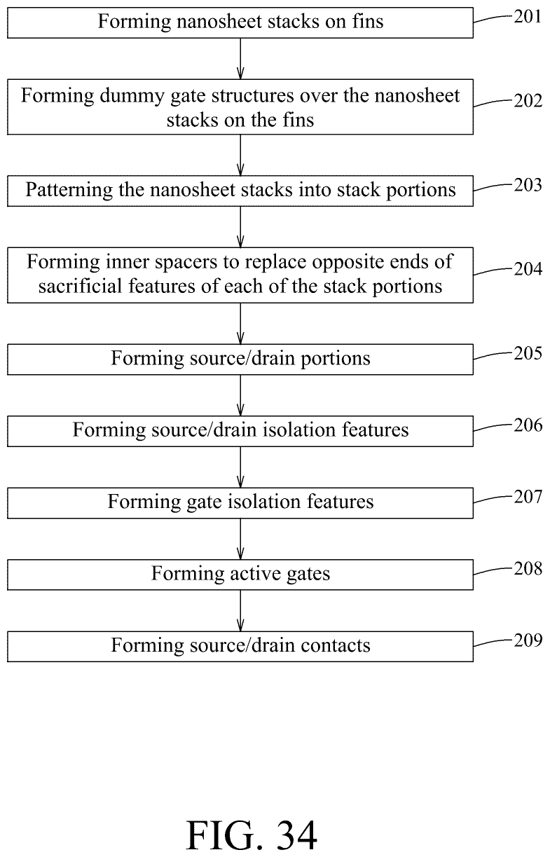

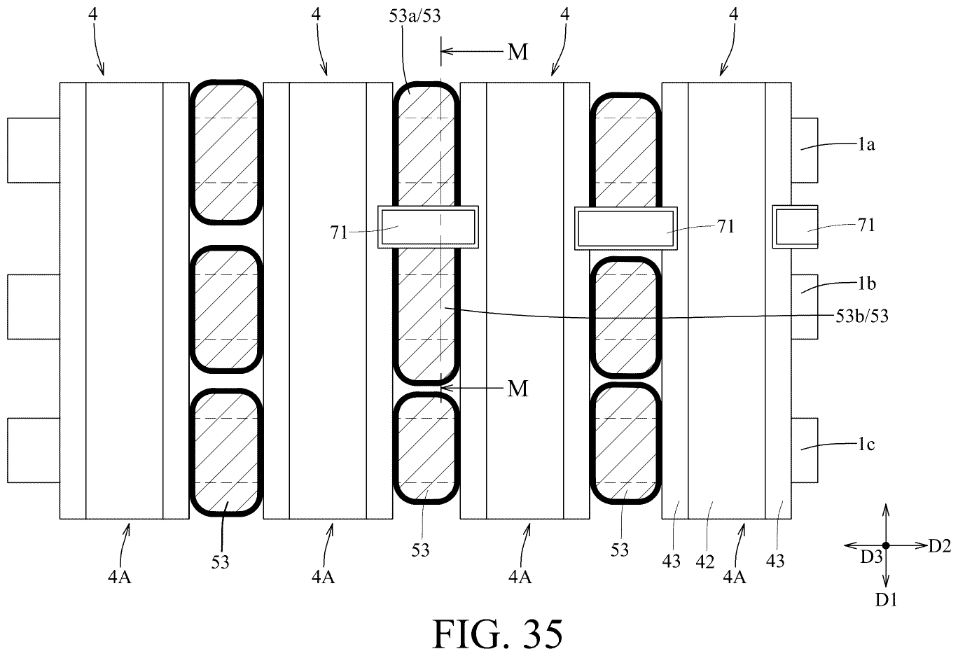

In the exemplary examples shown in FIGS. 1 to 33, the S/D isolation features 71 are formed after forming the active gate 4B of the active gate structures 40. FIGS. 34 to 42 illustrate, in some other embodiments, that the S/D isolation features 71 are formed after forming the S/D portions 53 and prior to forming the active gate 4B of the active gate structures 40. FIG. 34 is a flow diagram illustrating a method 200 for manufacturing the semiconductor structure (for example, the semiconductor structure shown in FIG. 40) in accordance with some embodiments. FIGS. 35 to 42 illustrate schematic views of intermediate stages of the method in accordance with some embodiments. Some repeating structures are omitted in FIGS. 35 to 42 for the sake of brevity. Additional steps can be provided before, after or during the method, and some of the steps described herein may be replaced by other steps or be eliminated. Please also note that hereinafter, some of the elements described are not shown in the figures for the sake of easy brevity.

Referring to FIG. 34, steps 201 to step 205 of the method 200 are respectively similar to steps 101 to step 105 of the method 100, and thus details thereof are omitted for the sake of brevity.

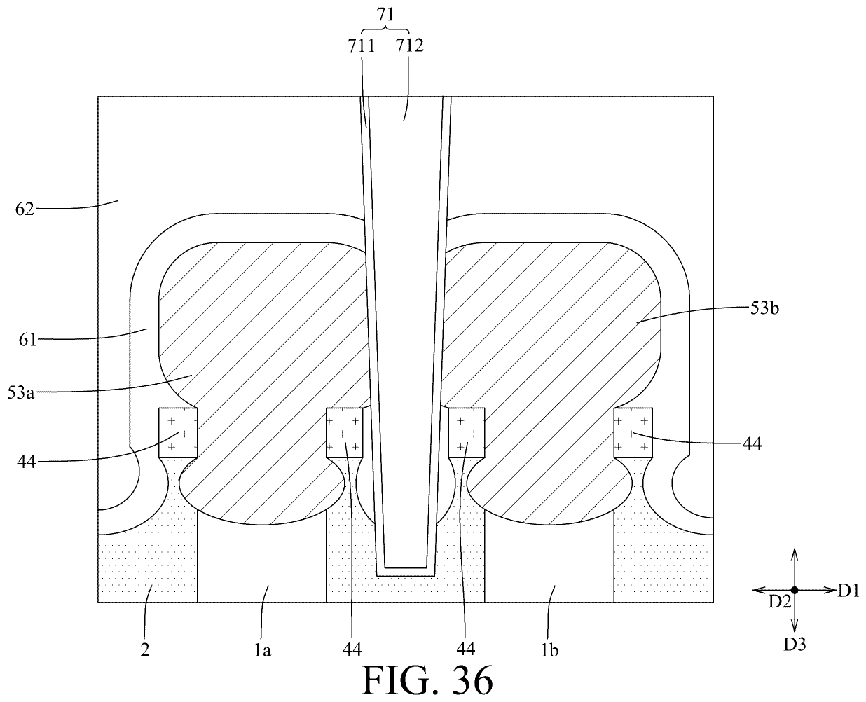

Referring to FIG. 34 and the example illustrated in FIGS. 35 to 36, the method 200 proceeds to step 206, where the S/D isolation features 71 are formed between two of the S/D portions 53 respectively on two adjacent ones of the fins 1a, 1b, c, and between two adjacent ones of the dummy gate structures 4. FIG. 35 is a top view of an intermediate structure after performing step 206 (some of the elements are not shown), while FIG. 36 is a cross sectional view of the intermediate structure along line M-M (at which one of the S/D isolation features 71 is formed) as shown in FIG. 35.

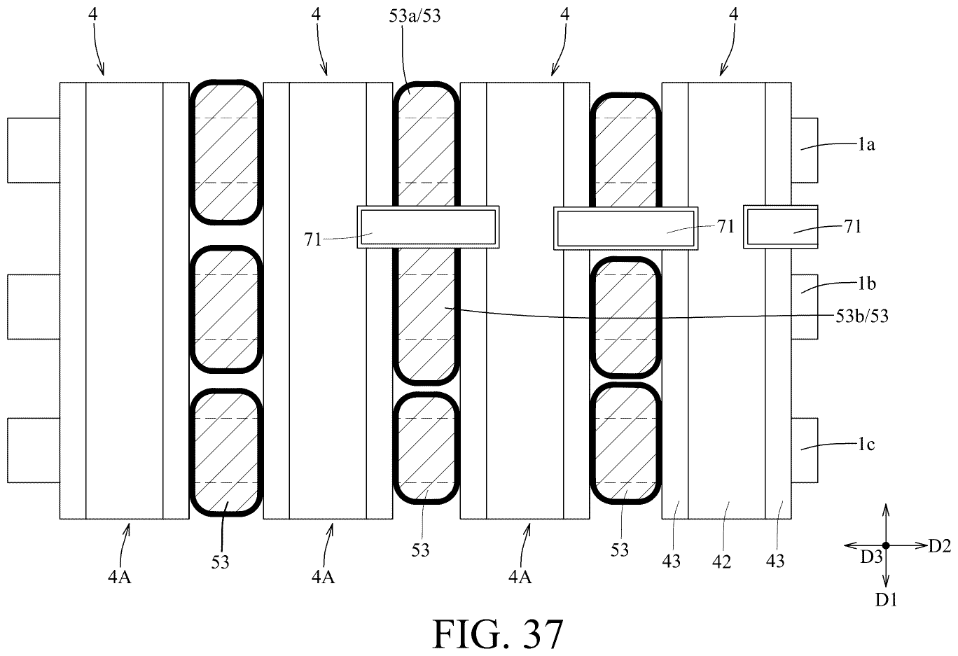

Step 206 of method 200 is similar to step 107 of method 100, except that in the second direction D2, each of the S/D isolation features 71 extends between the dummy gate 4A of the two adjacent ones of the dummy gate structures 4 (instead of the active gates 4B of the active gate structures 40 as shown in FIG. 16), without penetrating through the dummy gate 4A in the second direction D2. Similarly, in some embodiments, each of the two opposite ends (of each of the S/D isolation features 71) may terminate at the CESL 61, or the ILD 62 located between the two adjacent ones of the dummy gate structures 4. In other embodiments, the opposite ends of each of the S/D isolation features 71 may penetrate into the two adjacent ones of the dummy gate structures 4. In certain embodiments, as shown in FIG. 35, each of the two opposite ends (of each of the S/D isolation features 71) terminates at the proximal one of the two gate spacers 43 in the corresponding one of the two adjacent dummy gate structures 4. In some other embodiments, as shown in FIG. 37, each of the two opposite ends penetrates through the proximal one of the two gate spacers 43 in the corresponding one of the two adjacent dummy gate structures 4, so as to penetrate into and terminate at the dummy gate electrode 42 of the corresponding one of the two adjacent dummy gate structures 4. Despite the one S/D isolation feature 71 extending into the dummy gate electrodes 42 of the two adjacent dummy gate structures 4, such dummy gate electrodes 42 remain physically and electrically continuous in the first direction D1, and surrounds the two opposite ends of the one S/D isolation feature 71, respectively. In some other embodiments, each of the two opposite ends terminates at the gate dielectric 45 that is located between the dummy gate electrode 42 and the proximal one of the two gate spacers 43 in the corresponding one of the two adjacent dummy gate structures 4.

The S/D isolation features 71 are formed using similar processes and materials as described in method 100. For instance, the patterned mask is formed with openings exposing regions each of which is located between two of the S/D portions 53 respectively on adjacent ones of the fins 1a, 1b, 1c, and each of which is located between two adjacent ones of the dummy gates 4A. Please note that in the removal process (to form the cavities), the etchant employed in step 206 is capable to etch and remove the materials of the dummy dielectric 41 and the dummy gate electrode 42, in addition to the ILD 62, the CESL 61, the S/D portions 53, the isolation element 2, and the gate spacers 43. Other details thereof are similar to those described in step 107 of method 100 with reference to FIGS. 16 to 28, and details thereof are omitted for the sake of brevity.

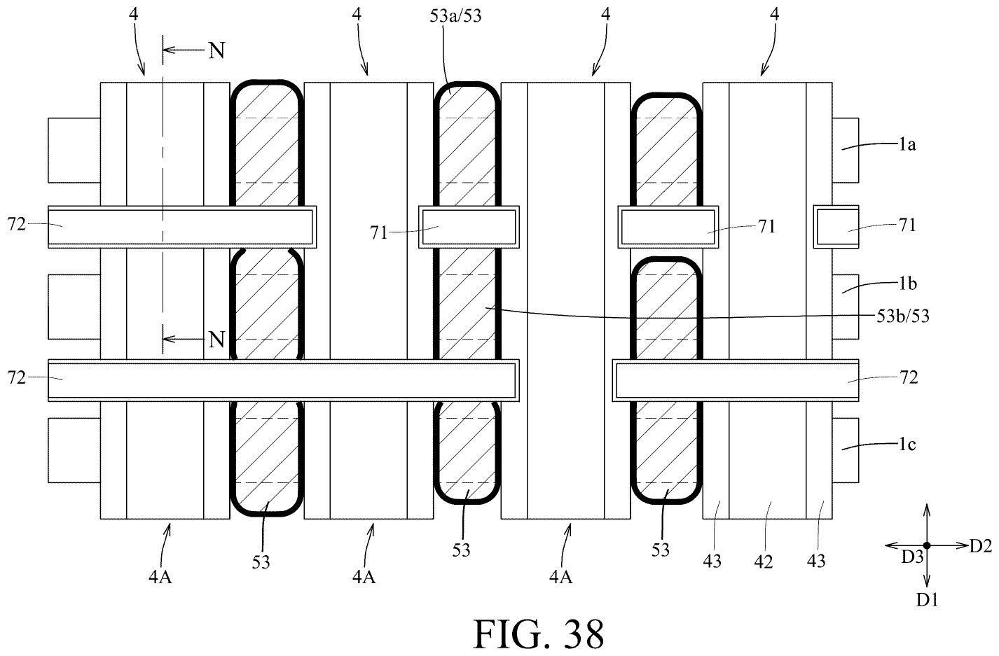

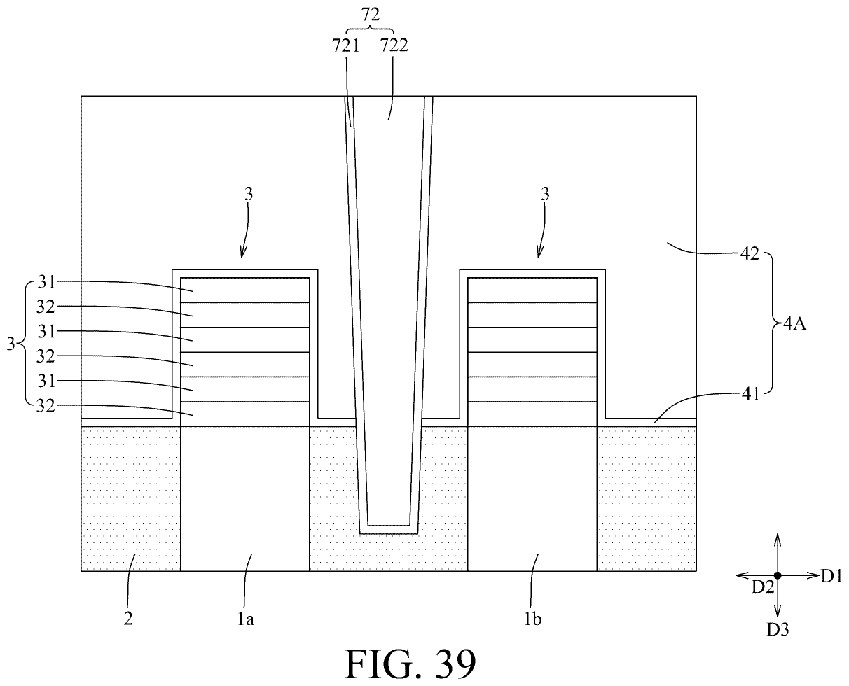

Referring to FIG. 34 and the example illustrated in FIGS. 38 to 39, the method 200 proceeds to step 207, where the gate isolation features 72 are formed, each of which separates a corresponding one of the dummy gates 4A into parts in the first direction D1. FIG. 38 is a top view of an intermediate structure after performing step 207 (some of the elements are not shown), while FIG. 39 is a cross-sectional view of the intermediate structure along line N-N (at which the gate isolation feature 72 is formed) as shown in FIG. 38.

Step 207 of method 200 is similar to step 108 of the method 100, except that in step 207, the gate isolation features 72 each penetrates through the dummy gates 4A and the gate spacers 43 of the adjacent ones of the dummy gate structures 4, instead of penetrating through the active gates 4B of the adjacent active gate structures 40 as described in step 108, so that each of the gate isolation features 72 divides a corresponding one of the dummy gate structures 4, which is originally continuous in the first direction D1 (see FIG. 35), into two parts (see FIG. 38). In some embodiments, each of the dummy gate structures 4 is divided into more than two parts by having more than one of the gate isolation features 72 penetrating therethrough. Other details of step 207 are omitted for the sake of brevity.

In addition, similar to step 107 and step 108 of method 100, step 206 and step 207 of method 200 (respectively for forming the S/D isolation features 71 and the gate isolation features 72) may also be formed in the same process, or may be formed sequentially. Other details thereof are omitted for the sake of brevity.

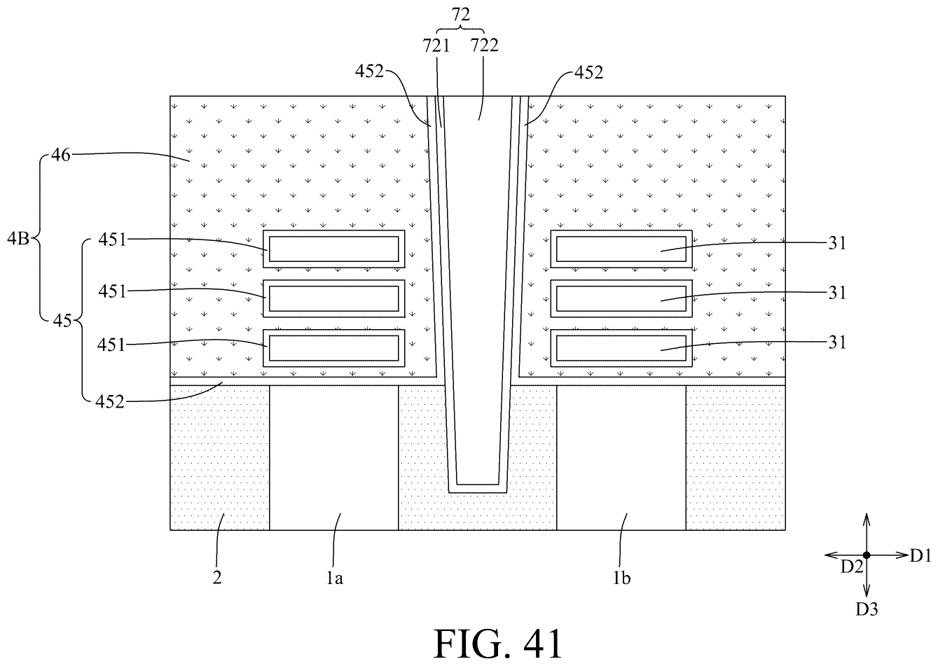

Referring to FIG. 34 and the example illustrated in FIGS. 40 to 41, the method 200 proceeds to step 208, where the active gates 4B are each formed to replace the dummy gate 4A of a corresponding one of the dummy gate structures 42 and the sacrificial features 32 of a corresponding one of the stack portions 30 on each of the fins 1a, 1b, 1c. FIG. 40 is a top view of an intermediate structure after performing step 208 (some of the elements are not shown), while FIG. 41 is a cross-sectional view of the intermediate structure along line O-O (in the first direction D1, at which one of the active gates 4B is formed) shown in FIG. 40.

Step 208 of method 200 is similar to step 106 of method 100, i.e., step 208 also includes: removing the dummy gates 4A of the dummy gate strictures 4; removing the sacrificial features 32 of each of the stack portions 30; and forming the active gates 4B, so as to obtain active gate structures 40. The difference between step 208 and step 106 is that, in step 208, the S/D isolation features 71 and the gate isolation features 72 are present and remain unaffected in removing the dummy gates 4A or the sacrificial features 32 (see also FIG. 39). As a result, in step 208, in forming the gate dielectric 45, the second portion 452 thereof is also formed on portions of the gate isolation features 72 (see FIG. 41) and also on portions of the S/D isolation features 71 (in the case of the structure shown in FIG. 37) that originally penetrate into the dummy gate 4A of the dummy gate structures 4, in addition to forming the second portion 452 of the gate dielectric 45 over the fins 1a, 1b, 1c, adjacent ones of the isolation elements 2, and the gate spacers 43 as discussed in step 106 of method 100. That is, the S/D isolation features 71 can be formed after (method 100), or prior to (method 200) formation of the active gates 4B of the active gate structures 40, such that the semiconductor structures obtained after method 200 and 100, respectively, (see FIGS. 29 and 40) have slight structural difference therebetween. Also, the gate isolation features 72 can be formed after or prior to formation of the active gates 4B of the active gate structures 40. For instance, in the structure shown in FIG. 40 (which is obtained by method 200), in each part of the active gate 4B, the gate dielectric 45 is formed between the gate isolation features 72 and the active gate electrode 46, i.e., the active gate electrode 46 is spaced apart from the gate isolation features 72 by the gate dielectric 45, whereas in the structure shown in FIG. 29 (which is obtained by method 100), the active gate electrode 46 is in direct contact with the gate isolation features 72. In other embodiments, the S/D isolation features 71 are formed before formation of the active gates 4B, and the gate isolation features 72 are formed after formation of the active gates 4B. In certain embodiments, the S/D isolation features 71 are formed after formation of the active gates 4B, and the gate isolation features 72 are formed before formation of the active gates 4B.

Referring to FIG. 34, the method further includes step 209, where S/D contacts 91 are formed penetrating into, and in direct contact with the S/D portions 53, respectively. Please note that step 209 is similar to step 109 of the method 100 with reference to FIG. 33, and thus details thereof are omitted.

The semiconductor structure manufactured using the method 200 may also have different configuration. For example, referring to FIG. 42, based on design of the semiconductor structure, some of the merging S/D regions 531 may be remained, the S/D isolation feature 71 is formed to penetrate through a selected one of the merging S/D regions 531 and terminates at the base 11. In addition, an etch stop layer (ESL) 92 and an ILD layer 93 are sequentially formed over the active gates 4B, the gate spacers 43, the CESL 61, the ILD 62 and the S/D isolation feature 71. In some embodiments, the ESL 92 includes silicon nitride, and the ILD 93 includes silicon oxide. Other suitable materials for the ESL and ILD 93 are within the contemplated scope of the present disclosure. In other embodiments, the semiconductor structure shown in FIG. 42 may also be manufactured using the method 100.

The embodiments of the present disclosure have the following advantageous features. By forming the S/D isolation features 71, the S/D portions 53 located on adjacent fins 1a, 1b, 1c, are physically and electrically, isolated from each other. Such isolation is beneficial to address merging issue, or bottom mushroom issue of the S/D portions 53 on adjacent fins 1a, 1b, 1c, so as to prevent short circuit of the semiconductor structure while keeping the spacing between the S/D portions 53 on the adjacent fins 1a, 1b, 1c small, thereby being conducive to improving the yield of the semiconductor structure. In addition, the S/D isolation features 71 are each formed with the width (W) of less than the CPP, so that resistance, or electrical conduction of the active gate electrodes 46 is minimally affected. In addition, the S/D isolation features 71 and the gate isolation features 72 can be formed in the same process, such that no additional mask is required.

In accordance with some embodiments of the present disclosure, a method for manufacturing a semiconductor structure includes: forming a nanosheet stack on each of a first fin and a second fin, the first fin and the second fin being spaced apart from each other in a first direction; forming dummy gate structures over the nanosheet stack on each of the first fin and the second fin, the dummy gate structures being spaced apart from each other in a second direction transverse to the first direction, each of the dummy gate structures including a dummy gate and two gate spacers at opposite sides of the dummy gate in the second direction; forming source/drain (S/D) portions in the nanosheet stack on each of the first fin and the second fin, such that the nanosheet stack is patterned into stack portions which alternate with the S/D portions in the second direction, and which are respectively covered by the dummy gate structures; forming active gates, each of which is formed to replace the dummy gate of a corresponding one of the dummy gate structures and sacrificial features of a corresponding one of the stack portions on each of the first fin and the second fin; and forming S/D isolation features between the first fin and the second fin such that each of the S/D isolation features isolates one of the S/D portions on the first fin from a respective one of the S/D portions on the second fin in the first direction, after forming the active gates, active gate structures are obtained, each of the active gate structures including one of the active gates and the two gate spacers of a corresponding one of the dummy gate structures, and after forming the active gates, each of the S/D isolations features extending in the second direction between two adjacent ones of the active gate structures in a manner that each of the S/D isolations features is prevented from penetrating through the active gates of two adjacent ones of the active gate structures.

In accordance with some embodiments of the present disclosure, the S/D isolation features are formed after forming the active gates and after forming the S/D portions.

In accordance with some embodiments of the present disclosure, the S/D isolation features are formed after forming the S/D portions and prior to forming the active gates.

In accordance with some embodiments of the present disclosure, the active gates are arranged in the second direction by a pitch, and each of the S/D isolation features has a width measured in the second direction which is less than the pitch.

In accordance with some embodiments of the present disclosure, after obtaining the active gate structures, each of the S/D isolation features has two opposite ends in the second direction that respectively terminates at the active gates of the two adjacent ones of the active gate structures.

In accordance with some embodiments of the present disclosure, after obtaining the active gate structures, each of the S/D isolation features has two opposite ends in the second direction, each of the two opposite ends terminating at a proximal one of the two gate spacers in a corresponding one of the two adjacent ones of the active gate structures.

In accordance with some embodiments of the present disclosure, each of the S/D isolation features is in direct contact with the one of the S/D portions on the first fin and the respective one of the S/D portions on the second fin.

In accordance with some embodiments of the present disclosure, each of the S/D isolation features includes a dielectric material that has a dielectric constant lower than a dielectric constant of a dielectric material of the gate spacers of the two adjacent ones of the active gate structures.

In accordance with some embodiments of the present disclosure, each of the S/D isolation features includes silicon nitride, silicon oxide, silicon oxynitride, silicon carbon nitride, silicon carbon oxynitride, silicon oxycarbide, hafnium oxide, aluminum oxide, or combinations thereof.

In accordance with some embodiments of the present disclosure, a method for manufacturing a semiconductor structure includes: forming a nanosheet stack on each of a first fin and a second fin, the first fin and the second fin being spaced apart from each other in a first direction; forming dummy gate structures over the nanosheet stack on each of the first fin and the second fin, the dummy gate structures being spaced apart from each other in a second direction transverse to the first direction, each of the dummy gate structures including a dummy gate and two gate spacers at opposite sides of the dummy gate in the second direction; forming source/drain (S/D) portions in the nanosheet stack on each of the first fin and the second fin, such that the nanosheet stack is patterned into stack portions which alternate with the S/D portions in the second direction, and which are respectively covered by the dummy gate structures; forming active gates, each of which is formed to replace the dummy gate of a corresponding one of the dummy gate structures and sacrificial features of a corresponding one of the stack portions on each of the first fin and the second fin; and forming S/D isolation features such that each of the S/D isolation features extends between two adjacent ones of the active gates without penetrating through the two adjacent ones of the active gates in the second direction, and such that each of the S/D portions on the first fin is spaced apart from a respective one of the S/D portions on the second fin in the first direction by a respective one of the S/D isolation features.

In accordance with some embodiments of the present disclosure, the method further includes forming gate isolation features, each of which separates a corresponding one of the active gates into two parts.

In accordance with some embodiments of the present disclosure, the gate isolation features and the S/D isolation features are formed in a same process.

In accordance with some embodiments of the present disclosure, the gate isolation features and the S/D isolation features are formed sequentially in different processes.

In accordance with some embodiments of the present disclosure, the gate isolation features are formed after forming the S/D isolation features, one of the gate isolation features penetrating into a corresponding one of the S/D isolation features.

In accordance with some embodiments of the present disclosure, the S/D isolation features are formed after forming the gate isolation features, one of the S/D isolation features penetrating into a corresponding one of the gate isolation features.

In accordance with some embodiments of the present disclosure, the active gates are arranged in the second direction by a pitch, and each of the S/D isolation features has a width measured in the second direction which is less than the pitch.

In accordance with some embodiments of the present disclosure, a semiconductor structure includes a first fin; a second fin; source/drain (S/D) portions; channel parts; active gate structures; and S/D isolation features. The first fin and the second fin are spaced apart from each other in a first direction. The S/D portions and the channel parts alternate with each other in a second direction transverse to the first direction on each of the first fin and the second fin. The active gate structures respectively includes active gates that are arranged in the second direction by a pitch, and that are formed around channels of a corresponding one of the channel parts on each of the first fin and the second fin. Each of the S/D isolation features isolates one of the S/D portions on the first fin and a respective one of the S/D portions on the second fin. Each of the S/D isolation features has a width measured in the second direction which is less than the pitch.

In accordance with some embodiments of the present disclosure, each of the active gate structures includes one of the active gates and two gate spacers at opposite sides of the one of the active gates in the second direction.

In accordance with some embodiments of the present disclosure, each of the S/D isolation features extends between two adjacent ones of the active gate structures, and having two opposite ends in the second direction, each of the two opposite ends being in direct contact with a proximal one of the two gate spacers of a corresponding one of the two adjacent ones of the active gate structures.

In accordance with some embodiments of the present disclosure, each of the S/D isolation features extends between two adjacent ones of the active gate structures, and having two opposite ends in the second direction that are respectively in direct contact with the active gates of the two adjacent ones of the active gate structures.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a nanosheet stack on each of a first fin and a second fin, the first fin and the second fin being spaced apart from each other in a first direction;
forming dummy gate structures over the nanosheet stack on each of the first fin and the second fin, the dummy gate structures being spaced apart from each other in a second direction transverse to the first direction, each of the dummy gate structures including a dummy gate and two gate spacers at opposite sides of the dummy gate in the second direction;
forming source/drain (S/D) portions in the nanosheet stack on each of the first fin and the second fin, such that the nanosheet stack is patterned into stack portions which alternate with the S/D portions in the second direction, and which are respectively covered by the dummy gate structures;
forming active gates, each of which is formed to replace the dummy gate of a corresponding one of the dummy gate structures and sacrificial features of a corresponding one of the stack portions on each of the first fin and the second fin; and
forming S/D isolation features between the first fin and the second fin such that each of the S/D isolation features isolates one of the S/D portions on the first fin from a respective one of the S/D portions on the second fin in the first direction,
after forming the active gates, active gate structures are obtained, each of the active gate structures including one of the active gates and the two gate spacers of a corresponding one of the dummy gate structures, and
after forming the active gates, each of the S/D isolations features extending in the second direction between two adjacent ones of the active gate structures in a manner that each of the S/D isolations features is prevented from penetrating through the active gates of two adjacent ones of the active gate structures.

2. The method according to claim 1, wherein the S/D isolation features are formed after forming the active gates and after forming the S/D portions.

3. The method according to claim 1, wherein the S/D isolation features are formed after forming the S/D portions and prior to forming the active gates.

4. The method according to claim 1, wherein the active gates are arranged in the second direction by a pitch, and each of the S/D isolation features has a width measured in the second direction which is less than the pitch.

5. The method according to claim 1, wherein after obtaining the active gate structures, each of the S/D isolation features has two opposite ends in the second direction that respectively terminates at the active gates of the two adjacent ones of the active gate structures.

6. The method according to claim 1, wherein after obtaining the active gate structures, each of the S/D isolation features has two opposite ends in the second direction, each of the two opposite ends terminating at a proximal one of the two gate spacers in a corresponding one of the two adjacent ones of the active gate structures.

7. The method according to claim 1, wherein each of the S/D isolation features is in direct contact with the one of the S/D portions on the first fin and the respective one of the S/D portions on the second fin.

8. The method according to claim 1, wherein each of the S/D isolation features includes a dielectric material that has a dielectric constant lower than a dielectric constant of a dielectric material of the gate spacers of the two adjacent ones of the active gate structures.

9. The method according to claim 1, wherein each of the S/D isolation features includes silicon nitride, silicon oxide, silicon oxynitride, silicon carbon nitride, silicon carbon oxynitride, silicon oxycarbide, hafnium oxide, aluminum oxide, or combinations thereof.

10. A method for manufacturing a semiconductor structure, comprising:
forming a nanosheet stack on each of a first fin and a second fin, the first fin and the second fin being spaced apart from each other in a first direction;
forming dummy gate structures over the nanosheet stack on each of the first fin and the second fin, the dummy gate structures being spaced apart from each other in a second direction transverse to the first direction, each of the dummy gate structures including a dummy gate and two gate spacers at opposite sides of the dummy gate in the second direction;
forming source/drain (S/D) portions in the nanosheet stack on each of the first fin and the second fin, such that the nanosheet stack is patterned into stack portions which alternate with the S/D portions in the second direction, and which are respectively covered by the dummy gate structures;
forming active gates, each of which is formed to replace the dummy gate of a corresponding one of the dummy gate structures and sacrificial features of a corresponding one of the stack portions on each of the first fin and the second fin; and
forming S/D isolation features such that each of the S/D isolation features extends between two adjacent ones of the active gates without penetrating through the two adjacent ones of the active gates in the second direction, and such that each of the S/D portions on the first fin is spaced apart from a respective one of the S/D portions on the second fin in the first direction by a respective one of the S/D isolation features.

11. The method according to claim 10, further comprising forming gate isolation features, each of which separates a corresponding one of the active gates into two parts.

12. The method according to claim 11, wherein the gate isolation features and the S/D isolation features are formed in a same process.

13. The method according to claim 11, wherein the gate isolation features and the S/D isolation features are formed sequentially in different processes.

14. The method according to claim 13, wherein the gate isolation features are formed after forming the S/D isolation features, one of the gate isolation features penetrating into a corresponding one of the S/D isolation features.

15. The method according to claim 13, wherein the S/D isolation features are formed after forming the gate isolation features, one of the S/D isolation features penetrating into a corresponding one of the gate isolation features.

16. The method according to claim 1, wherein the active gates are arranged in the second direction by a pitch, and each of the S/D isolation features has a width measured in the second direction which is less than the pitch.

17. A semiconductor structure, comprising:
a first fin and a second fin that are spaced apart from each other in a first direction;
source/drain (S/D) portions and channel parts that alternate with each other in a second direction transverse to the first direction on each of the first fin and the second fin;
active gate structures respectively including active gates that are arranged in the second direction by a pitch, and that are formed around channels of a corresponding one of the channel parts on each of the first fin and the second fin; and
S/D isolation features, each of which isolates one of the S/D portions on the first fin and a respective one of the S/D portions on the second fin, each of the S/D isolation features having a width measured in the second direction which is less than the pitch.

18. The semiconductor structure according to claim 17, wherein each of the active gate structures includes one of the active gates and two gate spacers at opposite sides of the one of the active gates in the second direction.

19. The semiconductor structure according to claim 18, wherein each of the S/D isolation features extends between two adjacent ones of the active gate structures, and having two opposite ends in the second direction, each of the two opposite ends being in direct contact with a proximal one of the two gate spacers of a corresponding one of the two adjacent ones of the active gate structures.

20. The semiconductor structure according to claim 18, wherein each of the S/D isolation features extends between two adjacent ones of the active gate structures, and having two opposite ends in the second direction that are respectively in direct contact with the active gates of the two adjacent ones of the active gate structures.
